(19) United States
(12) Patent Application Publication
(10) Pub. No.: US 2012/0076180 A1
(43) Pub. Date: Mar. 29, 2012

(54) PHASE-LOCKED LOOP AND RADIO COMMUNICATION DEVICE

(76) Inventor: Hiroaki HOSHINO, Kanagawa-ken (JP)

(21) Appl. No.: 13/178,922

(22) Filed: Jul. 8, 2011

(30) Foreign Application Priority Data
Sep. 29, 2010 (JP) 2010-219269

(51) Int. Cl. H03L 7/06; H04B 1/38

(52) U.S. Cl. 375/219; 327/157

(57) ABSTRACT

According to one embodiment, a phase-locked loop includes: a voltage controlled oscillator that generates an oscillation signal including an oscillation frequency corresponding to a control signal; a divider that divides the oscillation signal to generate a frequency-divided signal; a phase frequency detector that compares the phases of the frequency-divided signal and a reference signal to generate a comparison signal; a charge pump that outputs current corresponding to the comparison signal; a filter that filters the current to generate the control signal; a detection circuit that generates a detection signal when the difference between a value of a constant multiple of the frequency of the frequency-divided signal and a value of a constant multiple of the frequency of the reference signal becomes local minimum; and a phase adjustment circuit that synchronizes the phases of the frequency-divided signal and the reference signal when the detection signal is generated.

### CROSS-REFERENCES TO RELATED APPLICATION(S)

This application is based upon and claims the benefit of priority from the prior Japanese Patent Application No. 2010-219269 filed on Sep. 29, 2010, the entire contents of which are incorporated herein by reference.

### FIELD

Embodiments described herein relate generally to a phase-locked loop and a radio communication device.

### BACKGROUND

A phase-locked loop (PLL) for controlling the frequency of a voltage controlled oscillator (VCO) is used as a local oscillator (LO) used in a radio communication device. As a configuration of the PLL, a circuit using a phase frequency detector (PFD) and a charge pump (CP) is widely used. A typical PLL has a problem in that time (settling time) required to make its frequency stable at a desired value at the time when the frequency of the LO is changed is long.

As a method for shortening the settling time, there is a method that widens the loop band during transient response and narrows the loop band after the frequency has reached a desired value. However, in the case where a considerable frequency overshoot occurs during transient response, the settling time cannot be shortened sufficiently.

### BRIEF DESCRIPTION OF THE DRAWINGS

FIG. 1 is a block diagram illustrating a phase-locked loop according to a first embodiment of the present invention;

FIG. 2 is a block diagram illustrating a detailed configuration of a frequency difference detection circuit according to the first embodiment;

FIG. 3 is a view illustrating an example of comparison signals;

FIG. 4 is a view illustrating the frequency response of the phase-locked loop according to the first embodiment;

FIG. 5 is a block diagram illustrating a phase-locked loop according to a second embodiment of the present invention;

FIG. 6 is a view for explaining operation of a frequency detector according to the second embodiment;

FIG. 7 is a block diagram illustrating a phase-locked loop according to a third embodiment of the present invention;

FIG. 8 is a view for explaining operation of the phase-locked loop according to the third embodiment;

FIG. 9 is a block diagram illustrating a phase-locked loop according to a fourth embodiment of the present invention;

FIG. 10 is a view for explaining operation of the phase-locked loop according to the fourth embodiment;

FIG. 11 is a view illustrating a modification of the phase-locked loop according to the fourth embodiment;

FIG. 12 is a block diagram illustrating a phase-locked loop according to a fifth embodiment of the present invention;

FIG. 13 is a view for explaining operation of the phase-locked loop according to the fifth embodiment;

FIG. 14 is a view illustrating concrete configurations of first and second pulse width detection circuits;

FIG. 15 is a block diagram illustrating a phase-locked loop according to a sixth embodiment of the present invention;

FIG. 16 is a view illustrating a concrete configuration of a pulse width detection circuit 602;

FIG. 17 is a view for explaining operation of a phase-locked loop according to a seventh embodiment of the present invention;

FIG. 18 is a block diagram illustrating a phase-locked loop according to an eighth embodiment of the present invention;

FIG. 19 is a view for explaining operation of the phase-locked loop according to the eighth embodiment;

FIG. 20 is a block diagram illustrating a phase-locked loop according to a ninth embodiment of the present invention;

FIG. 21 is a block diagram illustrating a phase-locked loop according to a tenth embodiment of the present invention;

FIG. 22 is a block diagram illustrating a loop filter according to an eleventh embodiment of the present invention;

FIG. 23A-23D are a view for explaining operation of a typical loop filter;

FIG. 24 is a view for explaining operation of a phase-locked loop according to a twelfth embodiment of the present invention;

FIG. 25 is a block diagram illustrating a phase-locked loop according to a fourteenth embodiment of the present invention;

FIG. 26 is a view for explaining operation of the phase-locked loop according to the fourteenth embodiment; and

FIG. 27 is a block diagram illustrating a radio communication device according to a fifteenth embodiment of the present invention.

### DETAILED DESCRIPTION

According to one embodiment, a phase-locked loop includes: a voltage controlled oscillator that generates an oscillation signal including an oscillation frequency corresponding to a control signal; a divider that divides the oscillation signal to generate a frequency-divided signal; a phase frequency detector that compares the phases and frequencies of the frequency-divided signal and a reference signal to generate a comparison signal; a charge pump that outputs current corresponding to the comparison signal; a loop filter that filters the current to generate the control signal; a detection circuit that generates a detection signal when the difference between a value of a constant multiple of the frequency of the frequency-divided signal and a value of a constant multiple of the frequency the reference signal becomes local minimum; and a phase adjustment circuit that synchronizes the phases of the frequency-divided signal and the reference signal when the detection signal is generated.

Hereinafter, embodiments of the present invention will be described with reference to the accompanying drawings. Throughout the drawings, the same reference numerals refer to the same or similar parts, and redundant descriptions are omitted.

### First Embodiment

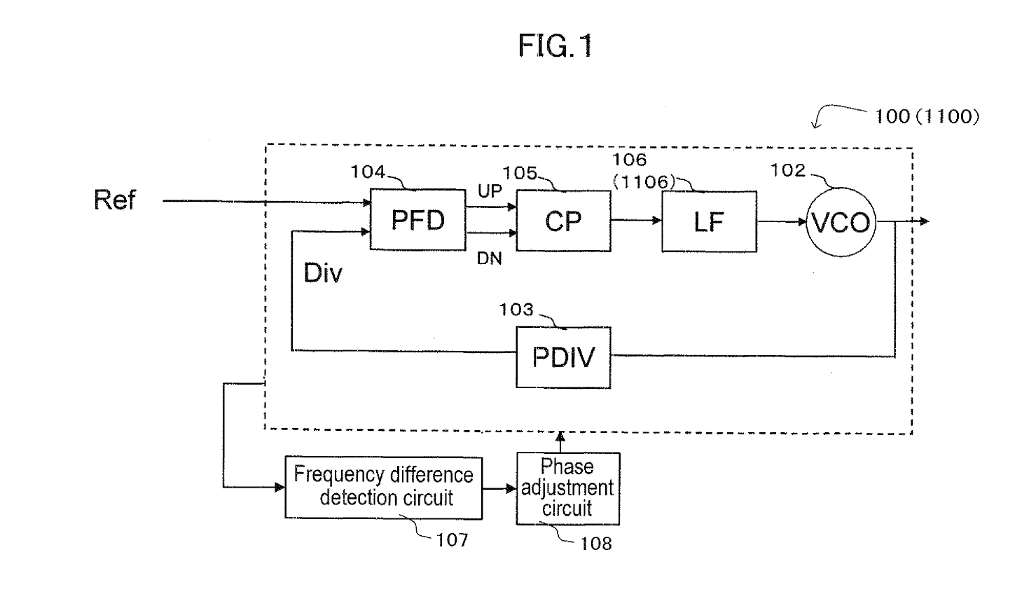

FIG. 1 is a block diagram illustrating a phase-locked loop (PLL) 100 according to a first embodiment.

The phase-locked loop 100 has: a voltage controlled oscillator (VCO) 102 that generates an oscillation signal including an oscillation frequency corresponding to a control signal; divider (DIV) 103 that divides the oscillation signal to generate a frequency-divided signal; a phase frequency detector (PFD) 104 that compares the phases of the frequency-divided signal and a reference signal to generate a comparison signal (pulse signal); a charge pump (CP) 105 that outputs current corresponding to the comparison signal; a loop filter (LP) 106 that filters current to generate a control signal; a frequency difference detection circuit 107 that generates a detection signal when the difference between value of a constant multiple of the frequency of the frequency-divided signal and a value of a constant multiple of the frequency of the reference signal becomes local minimum; and a phase adjustment circuit 108 that synchronizes the phases of the frequency-divided signal and the reference signal when the detection signal is generated.

Hereinafter, the components constituting the phase-locked loop 100 will be described more in detail.

The phase frequency detector 104 compares a reference signal REF and a frequency-divided signal Div and generates a comparison signal (pulse signal) for controlling the charge pump 105 of a subsequent stage based on the comparison result.

The charge pump 105 outputs current to the loop filter 106 based on the comparison signal. Concretely, the charge pump 105 supplies current to the loop filter 106 or draws current from the loop filter 106. The charge pump 105 has a plurality of current sources and a plurality of switches which are not illustrated.

The loop filter 106 converts the current supplied or drawn from the charge pump 105 into a control signal (control voltage).

The voltage controlled oscillator 102 generates an oscillation signal of an oscillation frequency that changes based on the control signal. The voltage controlled oscillator 102 may have positive or negative frequency gain with respect to the control signal. In this example, the voltage controlled oscillator 102 is assumed to have positive frequency gain.

The divider 103 divides the oscillation signal of the voltage controlled oscillator 102 and outputs the frequency-divided signal.

The frequency difference detection circuit 107 outputs a detection signal when the difference between a value of a constant multiple of the frequency of the frequency-divided signal and a value of a constant multiple of the frequency of the reference signal becomes local minimum. The value of a constant multiple may be one or more, and in the case where the value of a constant multiple is 1, the difference between a value of a constant multiple of the frequency of the frequency-divided signal and a value of a constant multiple of the frequency of the reference signal corresponds to the difference between the frequencies of the frequency-divided signal and the reference signal.

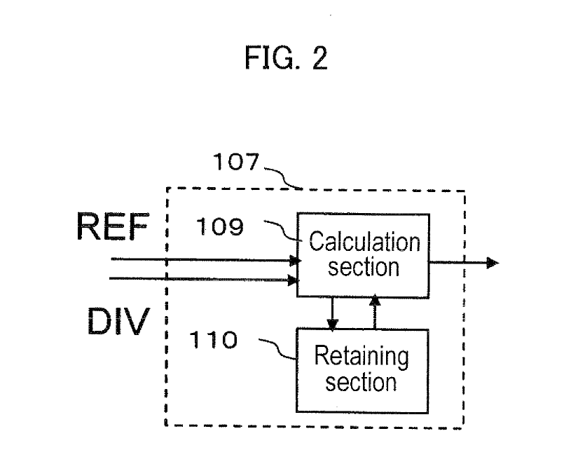

FIG. 2 is a bock diagram illustrating a detailed configuration of the frequency difference detection circuit 107. The frequency difference detection circuit 107 has: a calculation section 109 that calculates the difference between a value of a constant multiple of the frequency of the frequency-divided signal and a value of a constant multiple of the frequency of the reference signal; and retaining section 110 that retains the difference between a value of a constant multiple of the frequency of the frequency-divided signal and a value of a constant multiple of the frequency of the reference signal which is calculated by the calculation section 109. For example, the retaining section 110 retains the difference between a value of a constant multiple of the frequency of the frequency-divided signal and a value of a constant multiple of the frequency of the reference signal that the calculation section 109 previously calculated. In the case where the calculation section 109 calculates the difference between a value of a constant multiple of the frequency of the frequency-divided signal and a value of a constant multiple of the frequency of the reference signal for each period of the reference signal, the retaining section 110 retains the difference between a value of a constant multiple of the frequency of the frequency-divided signal and a value of a constant multiple of the frequency of the reference signal that the calculation section 109 calculated one period before the current reference signal. In the case where the calculation section 109 calculates the difference between a value of a constant multiple of the frequency of the frequency-divided signal and a value of a constant multiple of the frequency of the reference signal for each period of the frequency-divided signal, the retaining section 110 retains the difference between a value of a constant multiple of the frequency of the frequency-divided signal and a value of a constant multiple of the frequency of the reference signal that the calculation section 109 calculated one period before the current frequency-divided signal.

In the case where the plus and minus of the difference between a value of a constant multiple of the frequency of the frequency-divided signal and a value of a constant multiple of the frequency of the reference signal which is calculated by calculation section 109 and difference between a value of a constant multiple of the frequency of the frequency-divided signal and a value of a constant multiple of the frequency of the reference signal which is retained by the retaining section 110 are inverted, the frequency difference detection circuit 107 determines that the difference therebetween becomes local minimum. That is, in the case where the difference between a value of a constant multiple of the frequency of the frequency-divided signal and a value of a constant multiple of the frequency of the reference signal which is calculated by calculation section 109 is a negative value and where the difference between a value of a constant multiple the frequency of the frequency-divided signal and a value of a constant multiple of the frequency of the reference signal which is retained by the retaining section 110 is a positive value, the frequency difference detection circuit 107 determines that the difference therebetween becomes local minimum and outputs the detection signal. Alternatively, in the case where the difference between a value of a constant multiple of the frequency of the frequency-divided signal and a value of a constant multiple of the frequency of the reference signal which is calculated calculation section 109 is a positive value and where the difference between a value of a constant multiple of the frequency of the frequency-divided signal and a value of a constant multiple of the frequency of the reference signal which is retained by the retaining section 110 is a negative value, the frequency difference detection circuit 107 determines that the difference therebetween becomes local minimum and outputs the detection signal. In addition, in the case where the difference between a value of a constant multiple of the frequency of the frequency-divided signal and a value of a constant multiple of the frequency of the reference signal which is calculated by calculation section 109 is zero, the frequency difference detection circuit 107 determines that the difference therebetween becomes local minimum.

When inputting thereto the detection signal, the phase adjustment circuit 108 synchronizes the phases of the reference signal Ref and the frequency-divided signal Div so as to reduce the difference between the phases of the reference signal Ref and the frequency-divided signal Div. Concretely, the phase adjustment circuit 108 controls the divider 103 to adjust the phase of the frequency-divided signal to the phase of the reference signal. Alternatively, the phase adjustment circuit 108 may control the phase of the reference signal to adjust the phase of the reference signal to the phase of the frequency-divided signal. Concrete configuration and operation of the phase adjustment circuit 108 will be described later.

Next, the flow of a signal in the phase-locked loop 100 according to the present embodiment will be described.

The oscillation signal that the voltage controlled oscillator 102 generates is divided by the divider 103 to be converted into the frequency-divided signal. The frequency-divided signal is input to the phase frequency detector 104.

The phase frequency detector 104 compares the reference signal Ref and the frequency-divided signal Div and generates a comparison signal (first comparison signal or second comparison signal) corresponding to the phase difference between the reference signal Ref and the frequency-divided signal Div. Hereinafter, the first comparison signal is referred to as an UP signal, and second comparison signal is referred to as a DN signal.

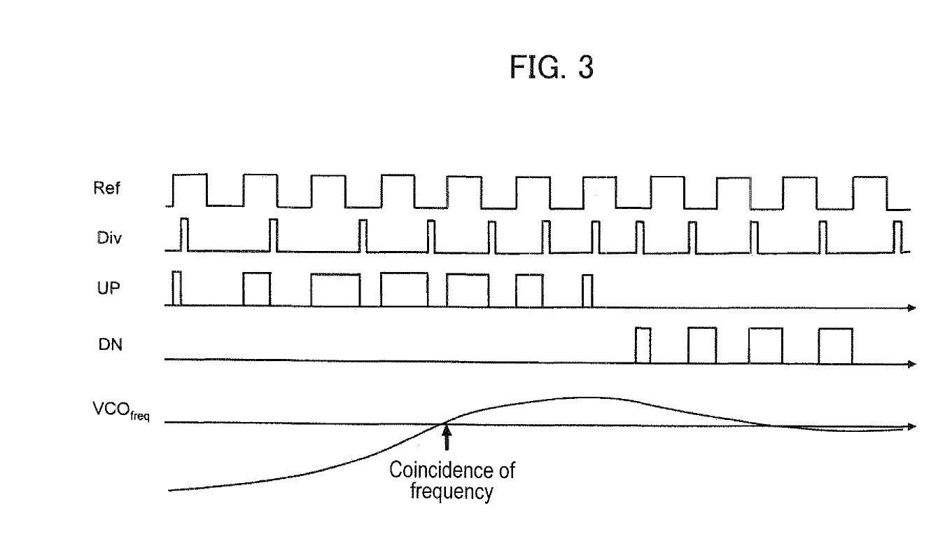

FIG. 3 illustrates an example of typical comparison signals. In the case where the phase of the reference signal Ref advances with respect to the phase of the frequency-divided signal Div, the phase frequency detector 104 generates the UP signal having a first pulse width ranging from the rising edge of the reference signal Ref to the rising edge of the frequency-divided signal. On the other hand, in the case where the phase of the frequency-divided signal Div advances with respect to the phase of the reference signal Ref, the phase frequency detector 104 generates the DN signal having a second pulse width ranging from the rising edge of the frequency-divided signal Div to the rising edge of the reference signal. In FIG. 3, the convex and concave parts of the pulse in both the UP and DN signals represent signal “HI” state and signal “LOW” state, respectively.

Although the UP signal and DN signal are each a signal having a pulse width defined between the rising edges of the reference signal and the frequency-divided signal in the above description, they may each be a signal having a pulse width defined between the falling edges of the reference signal and the frequency-divided signal.

The charge pump 105 supplies current to the loop filter 106 when the UP signal is HI and draws current from the loop filter 106 when the DN signal is HI. Here, a case is considered where, as illustrated in FIG. 3, the reference signal Ref is higher in frequency than the frequency-divided signal Div and the reference signal Ref advances in phase with respect to the frequency-divided signal Div at the signal start time. In the case where the reference signal Ref advances in phase with respect to the frequency-divided signal Div, the phase frequency detector 104 generates the UP signal. As described above, when the UP signal is HI, the charge pump 105 supplies current to the loop filter 106. Thus, the level of the control signal (control voltage) of the loop filter becomes high. The voltage controlled oscillator 102 has positive frequency gain, so that when the level of the control voltage becomes high, the oscillation frequency becomes high. As a result, the frequency of the frequency-divided signal Div which is the output of the divider 103 also becomes high. By the feedback as described above, the frequency of the frequency-divided signal Div is brought close to the frequency of the reference signal Ref and, finally, the frequencies thereof synchronize with each other.

In the example of FIG. 3, the phases of the reference signal and the frequency-divided signal are shifted from each other at the time point when the frequencies of the frequency-divided signal and the reference signal coincide with each other. The phase frequency detector 104 outputs the UP signal by the amount corresponding to the phase shift. As a result, the frequency of the frequency-divided signal becomes higher than the frequency of the reference signal. In a phase-locked loop not having the frequency difference detection circuit 107 and the phase adjustment circuit 108, the phases of the frequency-divided signal and the reference signal are shifted from each other even when the frequencies thereof coincide with each other, so that the frequencies of the frequency-divided signal and the reference signal do not coincide with each other immediately. That is, time (settling time) required for the frequencies of the frequency-divided signal and the reference signal to synchronize with each other becomes long.

On the other hand, the phase-locked loop 100 of this embodiment has the frequency difference detection circuit 107 and the phase adjustment circuit 108, and uses the frequency difference detection circuit 107 to detect a time point when the difference between a value of a constant multiple of the frequency of the reference signal Ref and a value of a constant multiple of the frequency of the frequency-divided signal Div becomes local minimum and then uses the phase adjustment circuit 108 to synchronize the phases of the reference signal Ref and the frequency-divided signal Div. As a result, the difference between the phases of the reference signal and the frequency-divided signal can be reduced, which in turn reduces frequency overshoot and shortens the settling time.

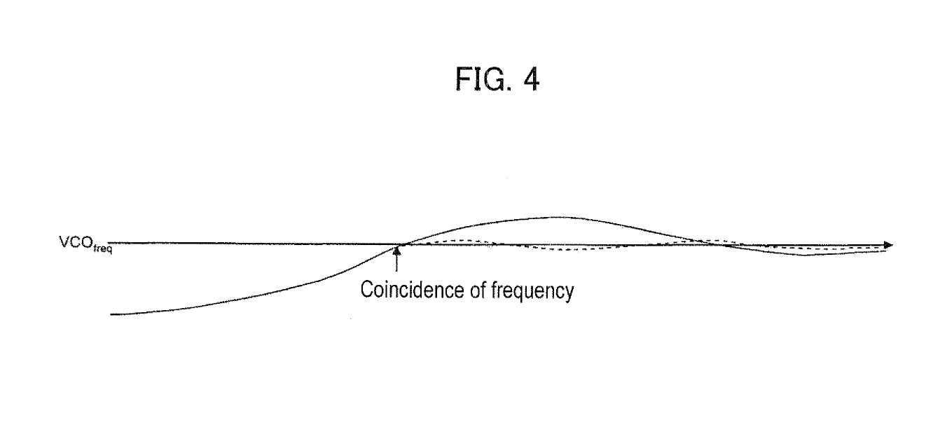

FIG. 4 is a view illustrating the frequency response of the phase-locked loop 100 according to the first embodiment. The solid curve of FIG. 4 represents the frequency response of a phase-locked loop (hereinafter, referred to as second phase-locked loop) not having the frequency difference detection circuit 107 and the phase adjustment circuit 108 and dotted curve line represents the frequency response of the phase-locked loop 100 having the frequency difference detection circuit 107 and the phase adjustment circuit 108.

As is clear from FIG. 4, overshoot in the frequency of the oscillation signal is reduced in the frequency response of the phase-locked loop 100 according to the present embodiment as compared with that according to the second phase-locked loop, and the time (settling time) required for the frequency of the oscillation signal to converge to a desired frequency is shortened.

According to the phase-locked loop 100 of the present embodiment, the settling time can be shortened by providing the frequency difference detection circuit 107 and the phase adjustment circuit 108.

Although the retaining section 110 of the phase-locked loop 100 of this embodiment retains, as the difference between a value of a constant multiple of the frequency of the reference signal and a value of a constant multiple of the frequency of the frequency-divided signal, the difference calculated one period before the current reference signal or frequency-divided signal, it may retain a difference calculated two or more periods before the current period of the reference signal or frequency-divided signal.

### Second Embodiment

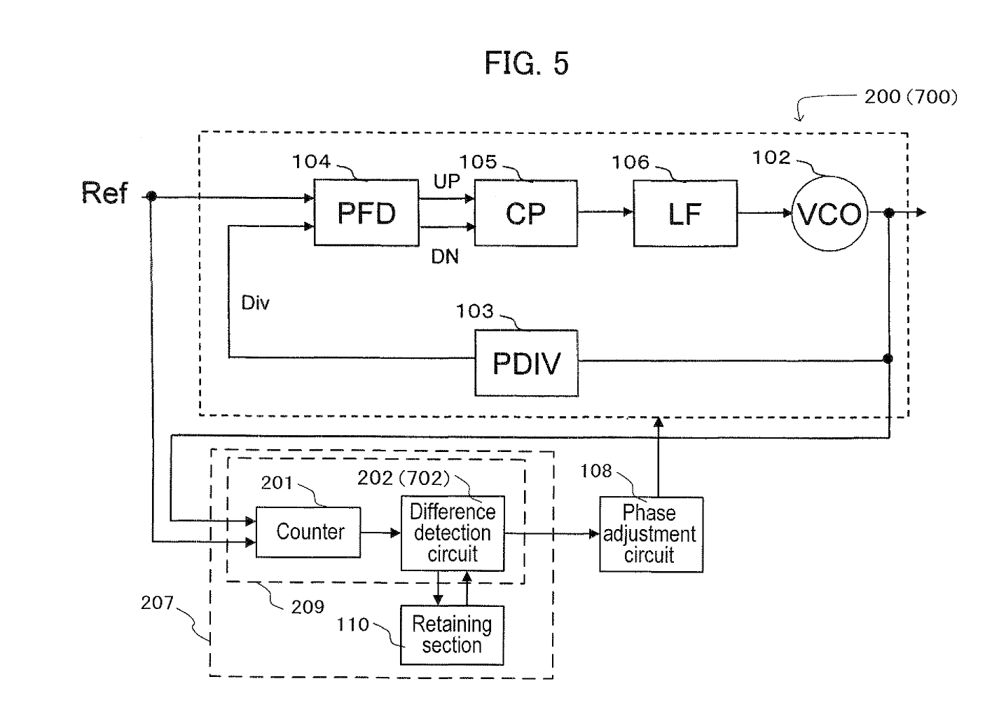

FIG. 5 is a block diagram illustrating a phase-locked loop 200 according to a second embodiment.

In the phase-locked loop 200 according to the second embodiment, the configuration of a frequency difference detection circuit 207 differs from that of the frequency difference detection circuit 107 of the phase-locked loop 100 according to the first embodiment. Other configurations are the same as those in the phase-locked loop 100 of the first embodiment.

The frequency difference detection circuit 207 has: a calculation section 209 constituted by a counter 201 and a difference detection circuit 202; and a retaining section 110. The calculation section 209 calculates the difference between a value of a constant multiple of the frequency of the frequency-divided signal and a value of a constant multiple of the frequency of the reference signal from the difference between the number of cycles of the oscillation signal included in one period of the reference signal and the frequency dividing number set in the divider 103.

The oscillation signal and the reference signal Ref are input to the counter 201. The counter 201 counts the number of cycles of the oscillation signal included in one period of the reference signal Ref and outputs the number of cycles counted.

The difference detection circuit 202 calculates the difference between the number of cycles counted by the counter 201 and frequency dividing number of the divider 103. This difference corresponds to the difference between a value of a constant multiple of the frequency of the frequency-divided signal and a value of a constant multiple of the frequency of the reference signal which is calculated by the frequency difference detection circuit 107 of the first embodiment. The difference calculated by the difference detection circuit 202 is retained in the retaining section 110. The difference detection circuit 202 compares the currently-calculated difference and difference calculated one period before the next one of the reference signal which is retained in the retaining section 110. The difference detection circuit 202 outputs a detection signal when the signs of the compared differences are changed therebetween.

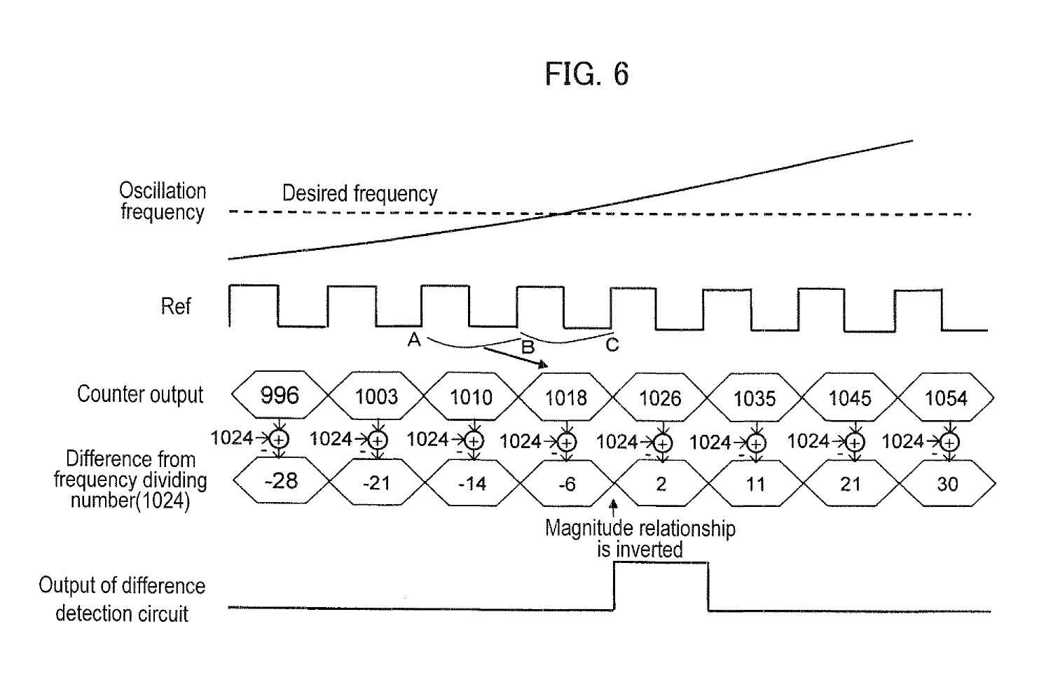

FIG. 6 is a view for explaining operation of the frequency difference detection circuit 207 according to the second embodiment. Hereinafter, a case is considered where the frequency dividing number set in the divider 103 is “1024”.

The counter 201 counts the number of cycles of the oscillation signal from the current rising edge or falling edge of the reference signal Ref to the next rising edge or falling edge (rising edge or falling edge one period after the current one thereof. In the example of FIG. 6, the counter 201 counts “1018” as the number of cycles of the oscillation signal included between rising edges A and B. The counter 201 outputs “1018” at the time point of the rising edge B.

The difference detection circuit 202 calculates which is the difference between the output “1018” of the counter 201 and frequency dividing number “1024” of the divider 103. When the calculated difference “−6” and “−14” which is the difference calculated one period before the current reference signal are compared, the signs of the differences are not changed therebetween. Thus, the difference detection circuit 202 does not output the detection signal but retains the calculated difference “−6” in the retaining section 110.

Then, the counter 201 counts “1026” as the number cycles of the oscillation signal included between rising edges B and C of the reference signal Ref. The counter 201 outputs “1026” at the time point of the rising edge C. The difference detection circuit 202 calculates which is the difference between the output “1026” of the counter 201 and frequency dividing number “1024” of the divider 103. The difference detection circuit 202 compares the calculated difference “2” and “−6” which is the difference calculated one period before the current reference signal retained in the retaining section 110. In this case, the signs of the differences are inverted to each other and thus the difference detection circuit 202 outputs the detection signal. That is, the detection of the sign of the difference by the difference detection circuit 202 allows detection of the timing at which the frequency of the frequency-divided signal is brought close to the frequency of the reference signal.

When the difference detection circuit 202 outputs the detection signal, the phase adjustment circuit 108 synchronizes the phases of the frequency-divided signal and the reference signal to reduce the difference between the phases of the frequency-divided signal and the reference signal.

As described above, according to the phase-locked loop of the present embodiment, the settling time can be shortened.

### Third Embodiment

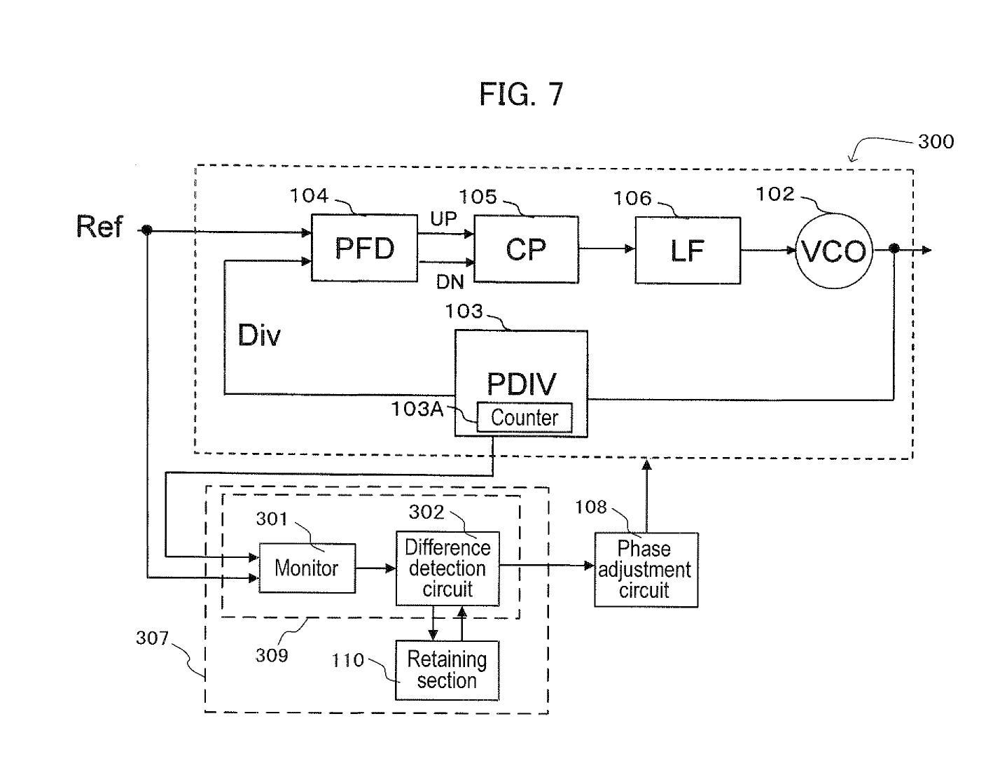

FIG. 7 is a block diagram illustrating a phase-locked loop 300 according to a third embodiment. In the phase-locked loop 300 according to the third embodiment, the configuration of a frequency difference detection circuit 307 differs from that of the frequency difference detection circuit 107 of the phase-locked loop 100 according to the first embodiment.

The frequency difference detection circuit 307 has: a calculation section 309 having a monitor 301 and a difference detection circuit 302 and a retaining section 110. The divider 103 has a counter 103A that counts the number of cycles of the oscillation signal and resets the oscillation signal cycle number to zero when it comes to the frequency dividing number of the divider 103.

The calculation section 309 calculates the difference between a value of a constant multiple of the frequency of the frequency-divided signal and a value of a constant multiple of the frequency of the reference signal from a value of the counter 103A and a value of the counter 103A counted one period before the current reference signal.

The monitor 301 monitors the value of the counter 103A of the divider 103 every reference signal Ref1 period and outputs the value of the counter 103A.

The difference detection circuit 302 calculates the difference between the value of the counter 103A and a value of the counter 103A counted one period before the current reference signal. This difference corresponds to the difference between a value of a constant multiple of the frequency of the frequency-divided signal and a value of a constant multiple of the frequency of the reference signal which is calculated by the frequency difference detection circuit 107 of the first embodiment. The difference calculated by the difference detection circuit 302 is retained in the retaining section 110. The difference detection circuit 302 compares the currently-calculated difference and difference calculated one period before the current reference signal which is retained in the retaining section 110 and outputs a detection signal when the signs of the differences are changed therebetween. The comparison between the differences allows detection of whether the frequency of the frequency-divided signal is higher or lower than the frequency of the reference signal.

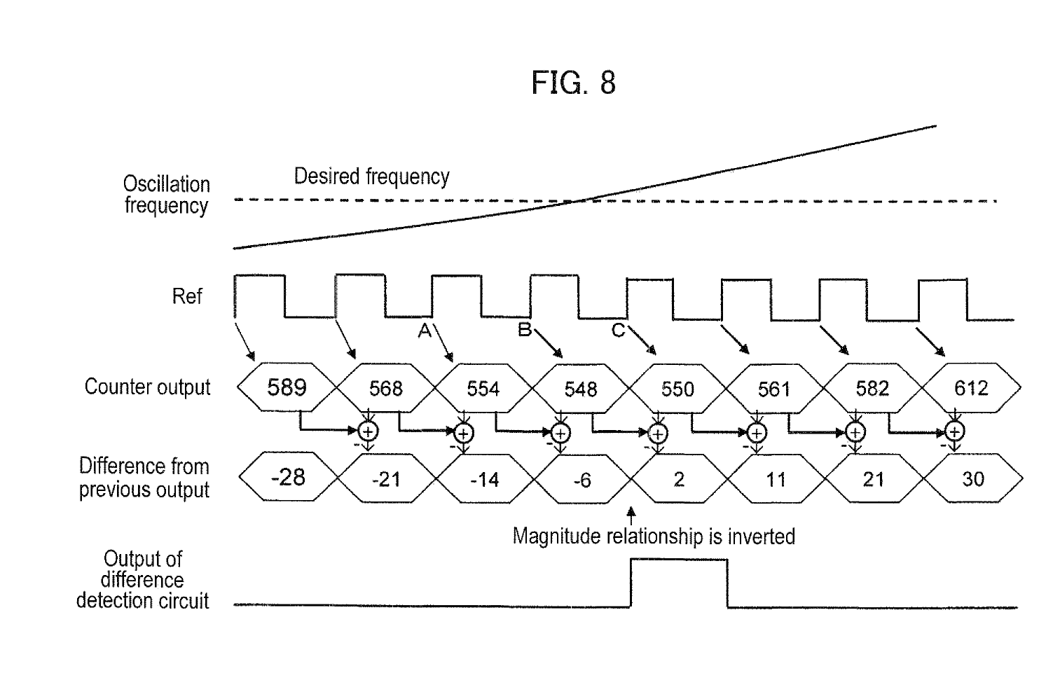

FIG. 8 is a view for explaining operation of the phase-locked loop 300 according to the third embodiment.

The monitor 301 monitors the value of the counter 103A of the divider 103 at the time point of the rising edge or falling edge of the reference signal Ref. The value of the counter 103A at the time point of a rising edge A is “554”. The monitor 103A outputs “554” as the value of the counter 103A at the rising edge A. Further, the monitor 103A monitors and outputs “548” as the value of the counter 103A at the rising edge B one period after the reference signal Ref. The difference detection circuit 302 calculates as the difference between the output “548” at the rising edge B and “554” at the rising edge A one period before the reference signal. The difference detection circuit 302 compares the calculated difference “−6” and “−14” which is the difference calculated one period before the reference signal. In this case, the signs of the differences are not changed therebetween, so that the difference detection circuit 302 does not output the detection signal but retains the calculated difference “−6” in the retaining section 110.

Then, the monitor 103A monitors and outputs “550” as the value of the counter 103A from the rising edge B of the reference signal Ref to a rising edge C one period after the reference signal Ref. The difference detection circuit 302 calculates “2” as the difference between the value of the counter 103A at the rising edge C and value of the counter 103A at the rising edge B one period before the reference signal. The difference detection circuit 302 compares the calculated difference “2” and difference “−6” one period before the reference signal which is retained in the retaining section 110. In this case, the signs of the differences are inverted to each other and thus the difference detection circuit 302 outputs the detection signal. With the above operation, the difference detection circuit 302 can detect that the signs of the differences are inverted to each other, thereby detecting the timing at which the frequency of the frequency-divided signal is brought close to the frequency of the reference signal.

When the difference detection circuit 302 outputs the detection signal, the phase adjustment circuit 108 synchronizes the phases of the frequency-divided signal and the reference signal to reduce the difference between the phases of the frequency-divided signal and the reference signal.

As described above, according to the phase-locked loop of the present embodiment, the settling time can be shortened.

### Fourth Embodiment

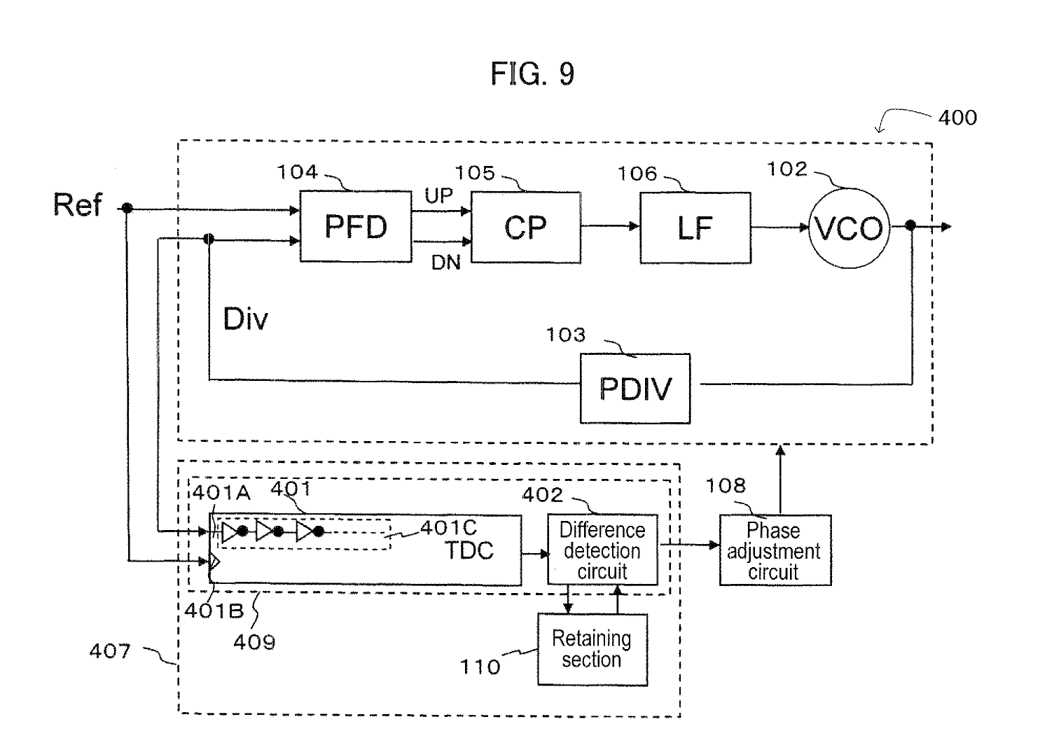

FIG. 9 is a block diagram illustrating a phase-locked loop 400 according to a fourth embodiment. In the phase-locked loop 400 according to the fourth embodiment, the configuration of a frequency difference detection circuit 307 differs from that of the frequency difference detection circuit 107 of the phase-locked loop 100 according to the first embodiment.

The frequency difference detection circuit 407 has: a calculation section 409 having a digital phase detector 401 (TDC: Time to digital converter) and a difference detection circuit 402 and a retaining section 110. The calculation section 409 detects the phase difference between the reference signal and the frequency-divided signal and calculates the difference between value of a constant multiple of the frequency of the frequency-divided signal and a value of a constant multiple of the frequency of the reference signal from the difference between the detected phase difference and phase difference detected one period before the current reference signal or frequency-divided signal.

The digital phase detector 401 has an input terminal 401A of a delay circuit 4010, a clock input terminal 4013 of a flip-flop (not illustrated), and a delay circuit 4010. The frequency-divided signal or signal in the divider 103 is input to the input terminal 401A of the delay circuit 401. The reference signal Ref is input to the clock input terminal 4013 of the flip-flop (not illustrated).

The digital phase detector 401 detects the phase difference between the reference signal and the frequency-divided signal. Concretely, the digital phase detector 401 detects the number of delay stages of the delay circuit corresponding to the delay measured from the time when the frequency-divided signal is input to the input terminal 401A of the delay circuit 4010 to the time when the reference signal is input to the clock input terminal 4010 of the flip-flop (not illustrated). The digital phase detector 401 detects the phase difference between the reference signal and the frequency-divided signal from the number of delay stages.

The difference detection circuit 402 calculates the difference between the number of delay stages detected by the digital phase detector 401 and number of delay stages calculated one period before the frequency-divided signal. This difference corresponds to the difference between a value of a constant multiple of the frequency of the frequency-divided signal and a value of a constant multiple of the frequency of the reference signal which is calculated by the frequency difference detection circuit 107 of the first embodiment. The difference calculated by the difference detection circuit 402 is retained in the retaining section 110. The difference detection circuit 402 compares the currently-calculated difference and difference calculated one period before the current frequency-divided signal which is retained in the retaining section 110 and outputs a detection signal when the signs of the compared differences are changed therebetween.

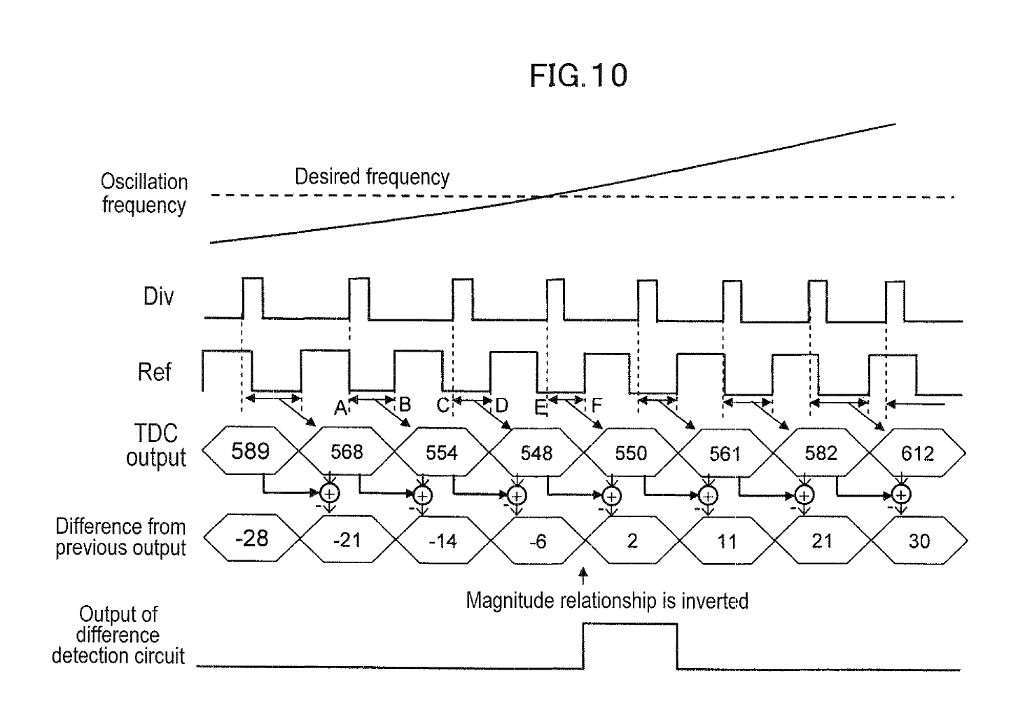

FIG. 10 is a view for explaining operation of the phase-locked loop 400 according to the fourth embodiment.

The frequency-divided signal Div and the reference signal Ref are input to the digital phase detector 401 through the input terminal 401A of the delay circuit 4010 and the clock input terminal 4010 of the flip-flop (not illustrated), respectively. The digital phase detector 401 detects the number of delay stages of the delay circuit corresponding to the delay of the reference signal with respect to the frequency-divided signal.

It is assumed in FIG. 10 that the time difference between a rising edge A of the frequency-divided signal Div and a rising edge B of the reference signal Ref is detected as the delay stage number “554” of the digital phase detector 401. Further, it is assumed in FIG. 10 that the time difference between a rising edge C of the frequency-divided signal Div one period after the frequency-divided signal Div and a rising edge D of the reference signal Ref one period after the reference signal Ref is detected as the delay stage number “548” of the digital phase detector 401. The difference detection circuit 402 calculates “−6” as the difference between the delay stage number between the rising edges C-D and delay stage number between the rising edges A-B. The difference detection circuit 402 compares the currently-calculated “−6” and “−14” which is the difference calculated one period before and detects that the signs of the compared differences are not changed therebetween. As a result, the difference detection circuit 402 does not output the detection signal but retains the calculated difference in the retaining section 110. Then, it is assumed that the digital phase detector 401 detects the time difference between a rising edge E of the frequency-divided signal one period after the rising edge C and a rising edge F of the reference signal Ref as a delay stage number “550” of the digital phase detector 401. The difference detection circuit 402 detects “2” as the difference between the delay stage number between the rising edges E-F and delay stage number between the rising edge C-D. The difference detection circuit 402 compares the currently-detected “2” and “−6” which is the difference calculated one period before which is retained in the retaining section 110. As a result, the difference detection circuit 402 detects that the sign of the difference is inverted to that of the previous difference. As a result, the difference detection circuit 402 outputs the detection signal.

When the difference detection circuit 402 outputs the detection signal, the phase adjustment circuit 108 synchronizes the phases of the frequency-divided signal and the reference signal to reduce the difference between the phases of the frequency-divided signal and the reference signal.

As described above, according to the phase-locked loop of the present embodiment, the settling time can be shortened.

In the present embodiment, a configuration is adopted in which the frequency-divided signal Div and the reference signal Ref are input to the digital phase detector 401 through the input terminal 401A of the delay circuit 401C and the clock input terminal 4013 of the flip-flop (not illustrated), respectively. Alternatively, however, the reference signal Ref and the frequency-divided signal Div may be input to the input terminal 401A of the delay circuit 401C and the clock input terminal 4013 of the flip-flop (not illustrated), respectively.

### (Modification)

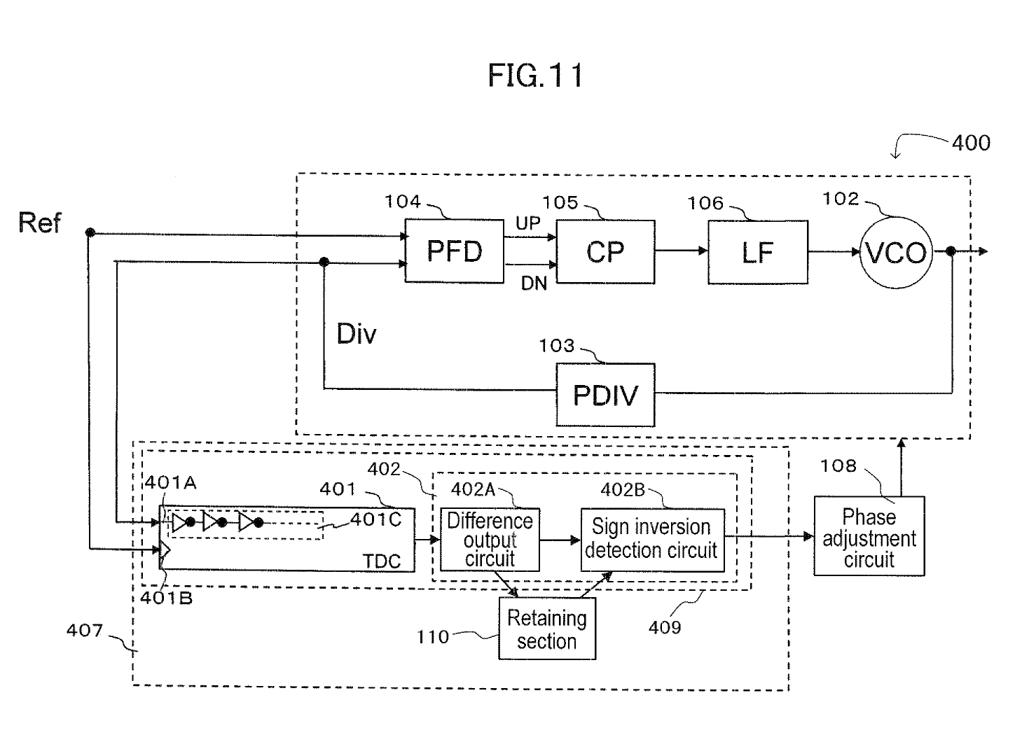

FIG. 11 illustrates a modification of the phase-locked loop of the present embodiment. In the present embodiment, the difference detection circuit 402 has a function of detecting the difference and detecting whether the signs of the differences are inverted between the detected difference and difference calculated one period before the detected difference are inverted or not. Alternatively, however, as illustrated in the modification of FIG. 11, a configuration may be adopted in which a difference output circuit 402A detects the difference and a sign inversion detection circuit 402B detects the sign inversion and outputs the detection signal when detecting the sign inversion.

### Fifth Embodiment

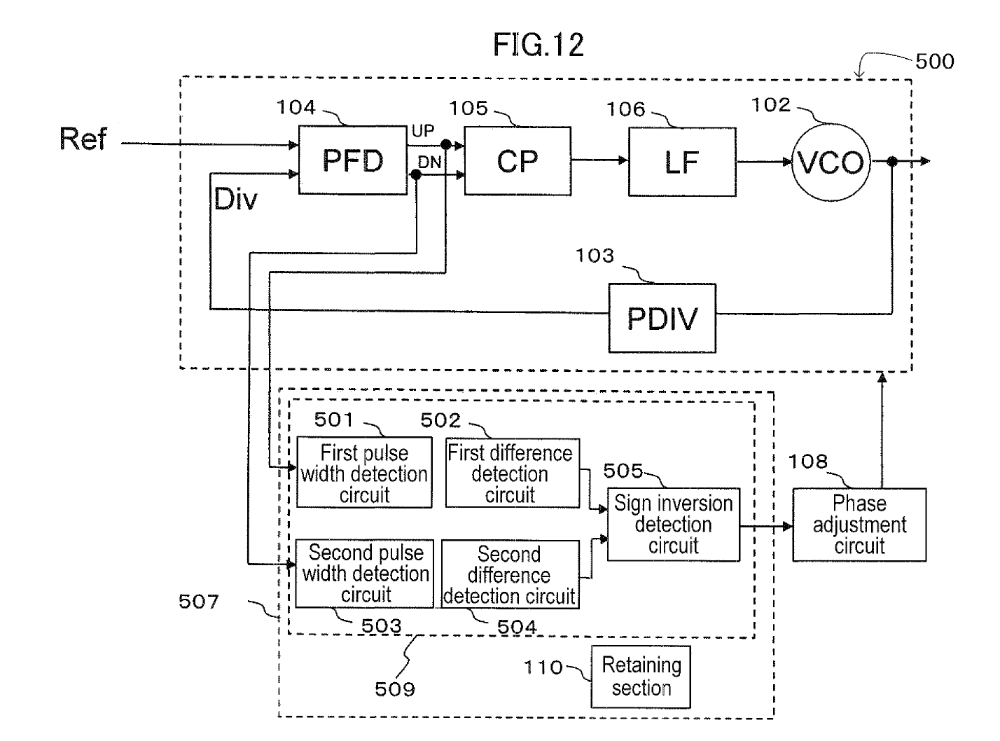

FIG. 12 is a block diagram illustrating a phase-locked loop 500 according to a fifth embodiment. In the phase-locked loop 500 according to the fifth embodiment, the configuration of a frequency difference detection circuit 507 differs from that of the frequency difference detection circuit 107 of the phase-locked loop 100 according to the first embodiment.

The frequency difference detection circuit 507 has a calculation section 509 and a retaining section 110. The calculation section 509 has a first pulse width detection circuit 501, a first difference detection circuit 502, a second pulse width detection circuit 503, a second difference detection circuit 504, and a sign inversion detection circuit 505.

The calculation section 509 detects the difference between a value of a constant multiple of the frequency of the frequency-divided signal and a value of a constant multiple of the frequency of the reference signal from the difference between a first pulse width which is the pulse width of the UP signal output from the phase frequency detector 104 or a second pulse width which is the pulse width of the DN signal output from the phase frequency detector 104 and previous first or second pulse width of the comparison signal (UP signal or DN signal).

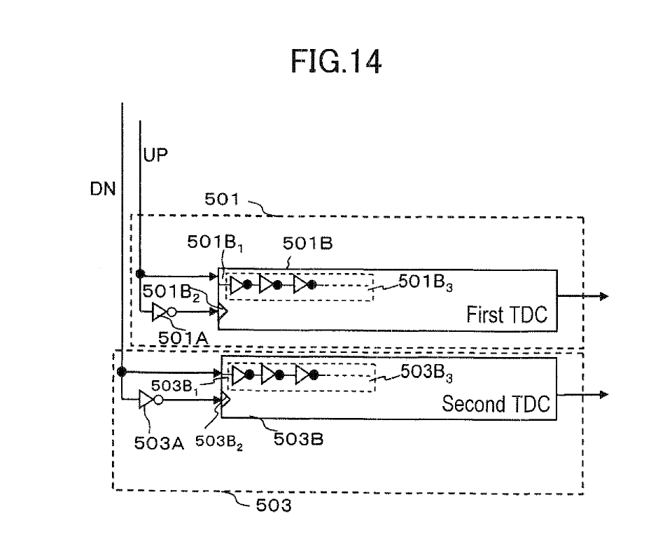

The first pulse width detection circuit 501 detects the first pulse width of the UP signal from the output of the phase frequency detector 104. FIG. 14 illustrates a concrete example of the first pulse width detection circuit 501 and the second pulse width detection circuit 503.

The first pulse width detection circuit 501 has a first inverter 501A and a first digital phase detector (first TDC) 501B. The UP signal output from the phase frequency detector 104 is input to an input terminal 501B₁ of a delay circuit 501B₃ of the first digital phase detector 501B. The UP signal is inverted by the first inverter 501A and is then input to the clock input terminal 501B₂ of the flip-flop (not illustrated) of the first digital phase detector 501B. The first digital phase detector 501B can detect the delay measured from the time when the rising edge of the UP signal is input to the input terminal 501B₁ of the delay circuit 501B₃ to the time when the inversion signal of the falling edge of the UP signal is input to the clock input terminal 501B₂ of the flip-flop (not illustrated) as the number of delay stages of the delay circuit 501B₃ of the first digital phase detector 501B. The number of delay stages is detected as the first pulse width of the UP signal.

The first difference detection circuit 502 detects the difference between the first pulse width of the UP signal detected by the first pulse width detection circuit 501 and the previous first pulse width of the UP signal. The retaining section 110 retains the calculated difference.

The second pulse width detection circuit 503 detects the second pulse width of the ON signal from the output of the phase frequency detector 104.

The second pulse width detection circuit 503 has a second inverter 503A and a second digital phase detector (second TDC) 503B. The ON signal output from the phase frequency detector 104 is input to an input terminal 503B₁ of a delay circuit 503B₃ of the second digital phase detector 503B. The ON signal is inverted by the second inverter 503A and is then input to the clock input terminal 503B₂ of the flip-flop (not illustrated) of the second digital phase detector 503B. The second digital phase detector 503B can detect the delay measured from the time when the rising edge of the ON signal is input to the input terminal 503B₁ of the delay circuit 503B₃ to the time when the inversion signal of the falling edge of the ON signal is input to the clock input terminal 503B₂ of the flip-flop (not illustrated) as the number of delay stages of the delay circuit 503B₃ of the second digital phase detector 503B. The number of delay stages is detected as the second pulse width of the ON signal.

The second difference detection circuit 504 detects the difference between the second pulse width of the ON signal detected by the second pulse width detection circuit 503 and the previous second pulse width of the ON signal. The retaining section 110 retains the calculated difference.

The sign inversion detection circuit 505 outputs the detection signal when the sign of the difference of the first or second pulse width is inverted. One of the difference between the first pulse widths or difference between the second pulse widths corresponds to the difference between a value of a constant multiple of the frequency of the frequency-divided signal and a value of a constant multiple of the frequency of the reference signal.

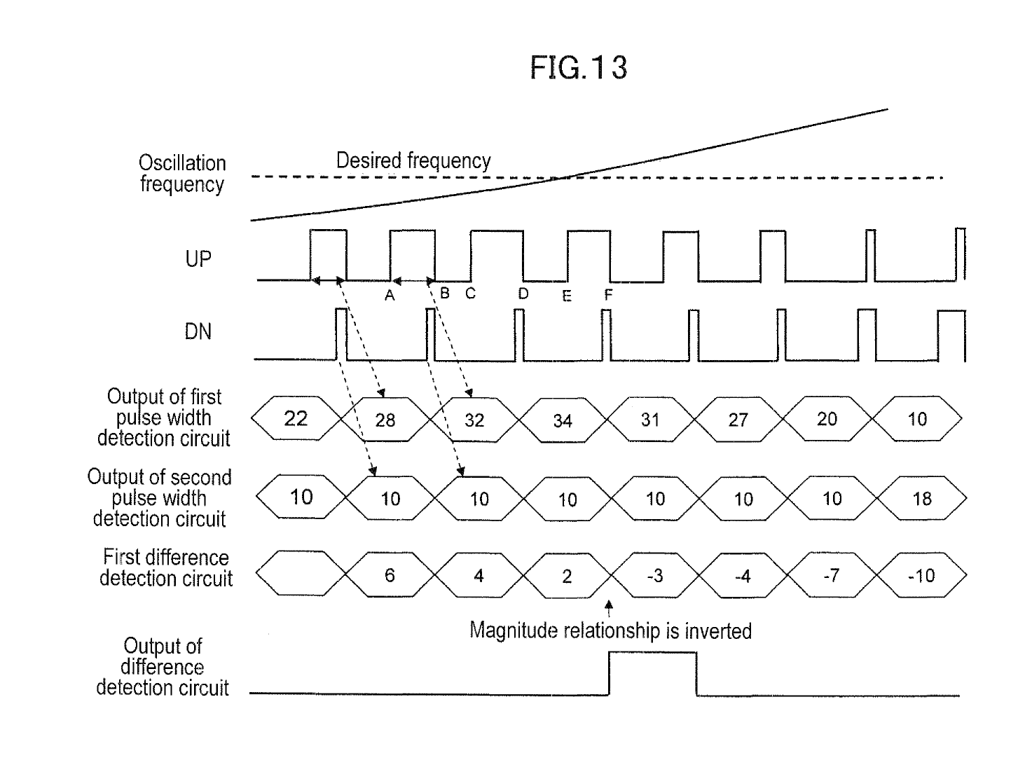

FIG. 13 is a view illustrating the phase-locked loop 500 according to the fifth embodiment.

The first pulse width detection circuit 501 detects the first pulse width of the UP signal, and the second pulse width detection circuit 503 detects the second pulse width of the ON signal. The first difference detection circuit 502 and the second difference detection circuit 504 each detect the difference in the pulse width from the previous data.

The sign inversion detection circuit 505 detects whether the sign of the difference between the first pulse widths or second pulse widths detected by the first difference detection circuit 502 or the second difference detection circuit 504 has been inverted or not. The sign inversion detection circuit 505 outputs the detection signal when detecting the sign inversion.

In the actual operation, when receiving as an input the difference output from the first difference detection circuit 502 and difference output from the second difference detection circuit 504, the sign inversion detection circuit 505 detects the inversion of the sign of the longer one of the first and second pulse widths and outputs the detection signal.

This is because, as is clear from FIG. 13, the difference between the shorter pulse widths is zero since the pulse width thereof is constant (in FIG. 13, the second pulse width is a constant value of 10). That is, usually, the sign inversion is not detected.

In the example of FIG. 13, the pulse width (first pulse width) of the UP signal is longer than the pulse width of the ON signal (second pulse width), and the sign inversion detection circuit 505 outputs the detection signal when the sign of the difference corresponding to the first pulse width is inverted.

The reason that a state where the difference between the shorter pulse widths is zero continues will be described below. In the example of FIG. 13, in the case where the phase of the reference signal advances with respect to the phase of the frequency-divided signal, the phase frequency detector 104 outputs the UP signal having a first pulse width (value larger than “10”) corresponding to the phase difference between the reference signal and the frequency-divided signal and outputs the DN signal having a constant second pulse width of “10” irrespective of the phase difference between the reference signal and the frequency-divided signal. On the other hand, in the case where the phase of the frequency-divided signal advances with respect to the phase of the reference signal, the phase frequency detector 104 outputs the ON signal having a second pulse width (value larger than “10”) corresponding to the phase difference between the frequency-divided signal and the reference signal and outputs the UP signal having a constant first pulse width of “10” irrespective of the phase difference between the reference signal and the frequency-divided signal.

That is, in the case where a state where the phase of the reference signal advances with respect to the phase of the frequency-divided signal continues, the phase frequency detector 104 continues outputting the DN signal having a second pulse width of “10” while in the case where a state where the phase of the frequency-divided signal advances with respect to the phase of the reference signal continues, the phase frequency detector 104 continues outputting the UP signal having a first pulse width of “10”. Thus, in the case where the phase of one of the reference signal and the frequency-divided signal advances with respect to the phase of the other one, a state where the difference between the shorter pulse widths is zero continues.

Therefore, usually, the sign inversion detection circuit 505 outputs the detection signal when the sign of the difference corresponding to the UP signal or DN signal, whichever is longer in pulse width, is inverted.

Although the phase frequency detector 104 outputs a signal having a pulse width of “10” when detecting nothing in the example of FIG. 13, a configuration may be possible in which the phase frequency detector 104 does not output the signal when detecting nothing.

In the example of FIG. 13, in the case where the UP signal has a longer pulse width than that of the DN signal and where the pulse width of the UP signal is equal to the previous pulse width thereof, there is no change in the delay of the frequency-divided signal with respect to the reference signal, so that the frequencies of the reference signal and the frequency-divided signal are equal to each other. Therefore, by detecting the timing at which a change in the pulse width of the UP signal becomes local minimum, that is, the timing at which the sign is inverted, it is possible to detect the timing at which the frequencies of the frequency-divided signal and the reference signal are substantially equal to each other.

In FIG. 13, the first pulse width detection circuit 501 detects that the pulse width between a rising edge A of the UP signal and a falling edge B is “32”, pulse width between a rising edge C and a falling edge D is “34”, and pulse width between a rising edge E and a falling edge F is “31”. The first difference detection circuit 502 calculates a difference “2” at the timing of the falling edge D and calculates “−3” at the falling edge F. Thus, at the timing of the falling edge F, the sign inversion detection circuit 505 detects the inversion of the sign of the difference and outputs the detection signal.

When the sign inversion detection circuit 505 outputs the detection signal, the phase adjustment circuit 108 synchronizes the phases of the frequency-divided signal and the reference signal to reduce the difference between the phases of the frequency-divided signal and the reference signal.

As described above, according to the phase-locked loop of the present embodiment, the settling time can be shortened.

### Sixth Embodiment

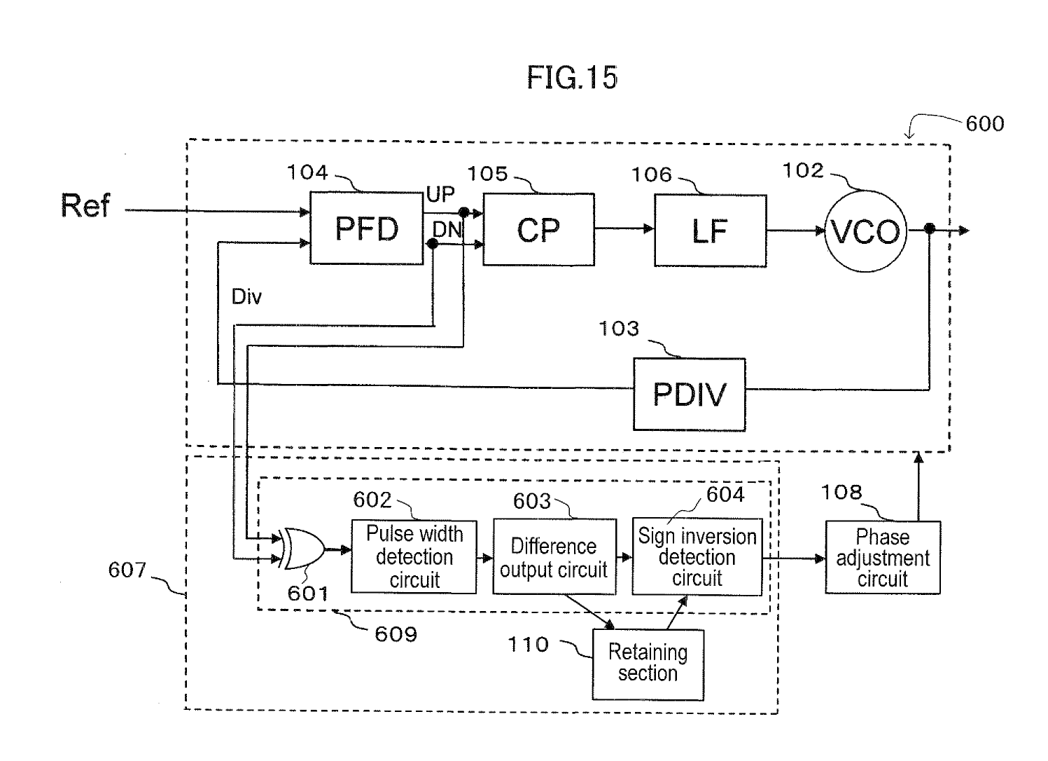

FIG. 15 is a block diagram illustrating a phase-locked loop 600 according to a sixth embodiment. In the phase-locked loop 600 according to the six embodiment, the configuration of a frequency difference detection circuit 607 differs from that of the frequency difference detection circuit 107 of the phase-locked loop 100 according to the first embodiment.

The frequency difference detection circuit 607 has a calculation section 609 and a retaining section 110. The calculation section 609 has a logic circuit 601, a pulse width detection circuit 602, a difference output circuit 603, and a sign inversion detection circuit 604.

The logic circuit 601 outputs a third comparison signal which is the exclusive OR of the UP signal and the ON signal output from the phase frequency detector 104.

The pulse width detection circuit 602 detects the pulse width of the third comparison signal.

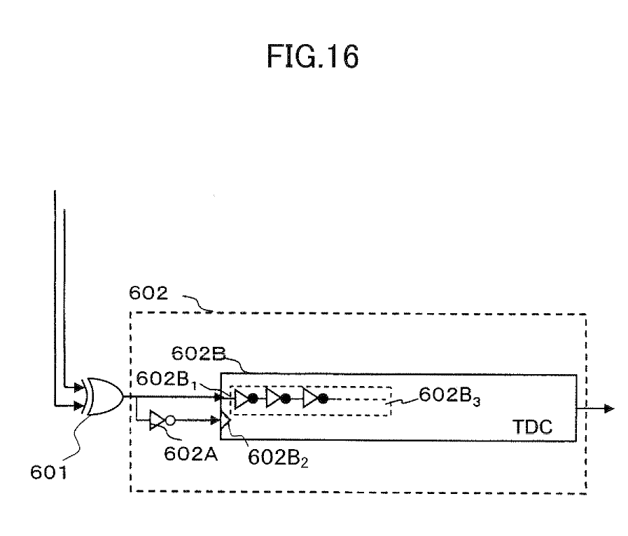

FIG. 16 illustrates a concrete configuration of the pulse width detection circuit 602.

The pulse width detection circuit 602 has an inverter 602A and a digital phase detector (TDC) 602B. The third comparison signal is input to an input terminal 602B₁ of a delay circuit 602B₃ of the digital phase detector 602B. The sign of the third comparison signal is inverted by the inverter 602A and is then input to a clock input terminal 602B₂ of a flip-flop (not illustrated) of the digital phase detector 602B. The digital phase detector 602B can detect the delay measured from the time when the rising edge of the third comparison signal is input to the input terminal 602B₁ of the delay circuit 602B₃ to the time when the inversion signal of the falling edge of the third comparison signal is input to the clock input terminal 602B₂ of the flip-flop (not illustrated) as the number of delay stages of the delay circuit 602B₃ of the digital phase detector 602B. The number of delay stages is detected as the first pulse width of the third comparison signal.

The difference output circuit 603 detects the difference between the pulse width of the third comparison signal detected by the pulse width detection circuit 602 and the previous one detected by the pulse width detection circuit 602. As illustrated in FIG. 13, one of the UP signal and DN signal of the third comparison signal is constant and the other one thereof changes. In the case where the phase of the frequency-divided signal delays with respect to the phase of the reference signal, the pulse width of the UP signal changes while the pulse width of the DN signal is constant. In this case, the difference output circuit 603 detects the difference between the pulse widths of the UP signal. On the other hand, in the case where the phase of the reference signal delays with respect to the phase of the frequency-divided signal, the difference output circuit 603 detects the difference between the pulse widths of the ON signal.

The retaining section 110 detects the calculated difference.

The sign inversion detection circuit 604 outputs the detection signal when the sign of the difference input from the difference output circuit 603 is inverted. One of the difference between the pulse widths of the UP signal and difference between the pulse widths of the ON signal is input to the sign inversion detection circuit 604. The sign inversion detection circuit 604 detects the timing at which the sign of the difference is inverted to thereby detect the timing at which the difference between the frequencies of the frequency-divided signal and the reference signal becomes local minimum.

When the sign inversion detection circuit 604 outputs the detection signal, the phase adjustment circuit 108 synchronizes the phases of the frequency-divided signal and the reference signal to reduce the difference between the phases of the frequency-divided signal and the reference signal.

As described above, according to the phase-locked loop of the present embodiment, the settling time can be shortened.

### Seventh Embodiment

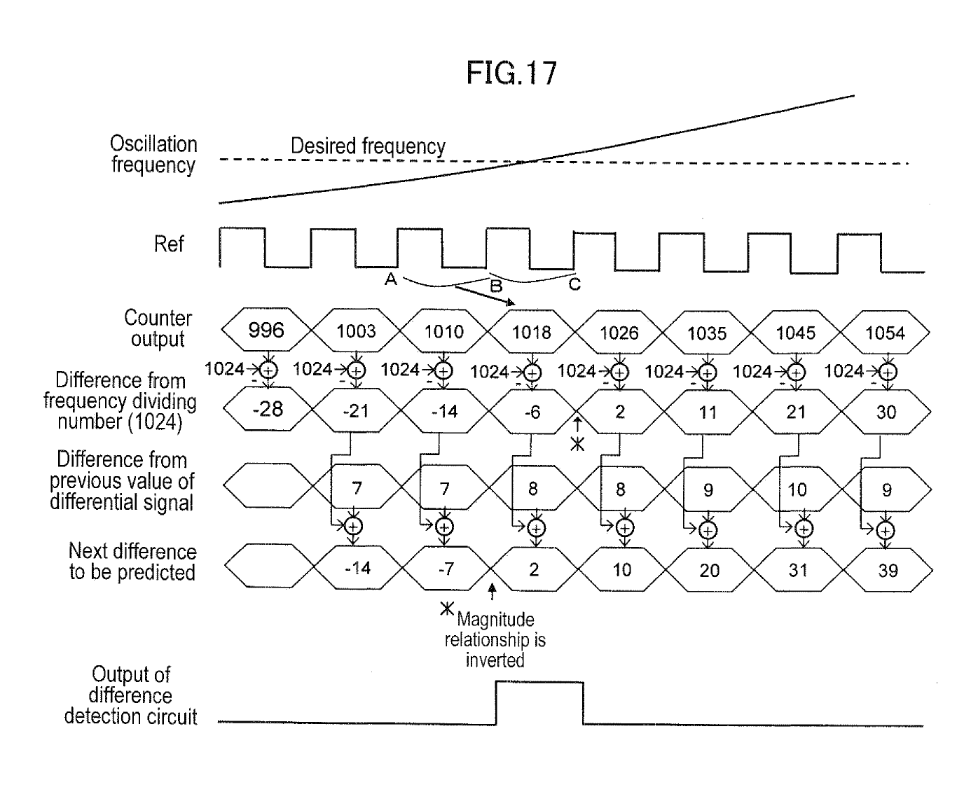

A phase-locked loop 700 according to a seventh embodiment will be described. The phase-locked loop 700 according to the seventh embodiment has the same configuration as that of the phase-locked loop 200 according to the second embodiment of FIG. 5. FIG. 17 is a view for explaining operation of the phase-locked loop 700 of the seventh embodiment. The phase-locked loop 700 of the seventh embodiment will be described using FIGS. 5 and 17. In the phase-locked loop 700 according to the present embodiment, the function of a difference detection circuit 702 differs from that of the difference detection circuit 202 of the phase-locked loop 200 of the second embodiment.

In the phase-locked loop 200 according to the second embodiment, the difference detection circuit 202 detects the inversion of the sign of the difference.

In the phase-locked loop 700 of the present embodiment, the difference detection circuit 702 calculates the difference between a currently-calculated difference and difference one period before. The difference detection circuit 702 then calculates the sum of the difference between a currently-calculated difference and difference one period before and difference currently-calculated by the difference detection circuit 702 to predict the difference that the difference detection circuit 702 will calculate next. The difference detection circuit 702 predicts the difference that the difference detection circuit 702 itself will calculate next to output the detection signal before the inversion of the sign of the difference.

For example, in FIG. 17, the difference detection circuit 702 calculates “7” as the difference between a difference “−21” currently-calculated and a difference “−28” calculated one period before. The difference detection circuit 702 calculates “−14” which is the sum of the calculated difference “−21” and difference “7”. This “14” is the prediction value of the difference to be calculated by the difference detection circuit 702. In this manner, the difference detection circuit 702 calculates the prediction value of the difference for each period. In the example of FIG. 17, the difference detection circuit 702 calculates the prediction value “−14” and then calculates “−7” and “2”, sequentially. Since the sign of the prediction value of the difference is inverted, the difference detection circuit 702 outputs the detection signal.

According to the phase-locked loop 700 of the present embodiment, the difference detection circuit 702 can output the detection signal before the actual inversion of the sign of the difference.

When the difference detection circuit 702 outputs the detection signal, the phase adjustment circuit 108 synchronizes the phases of the frequency-divided signal and the reference signal to reduce the difference between the phases of the frequency-divided signal and the reference signal.

As described above, according to the phase-locked loop 700 of the present embodiment, the phases of the frequency-divided signal and the reference signal can be synchronized with each other at an earlier timing, so that the settling time can further be shortened.

### Eighth Embodiment

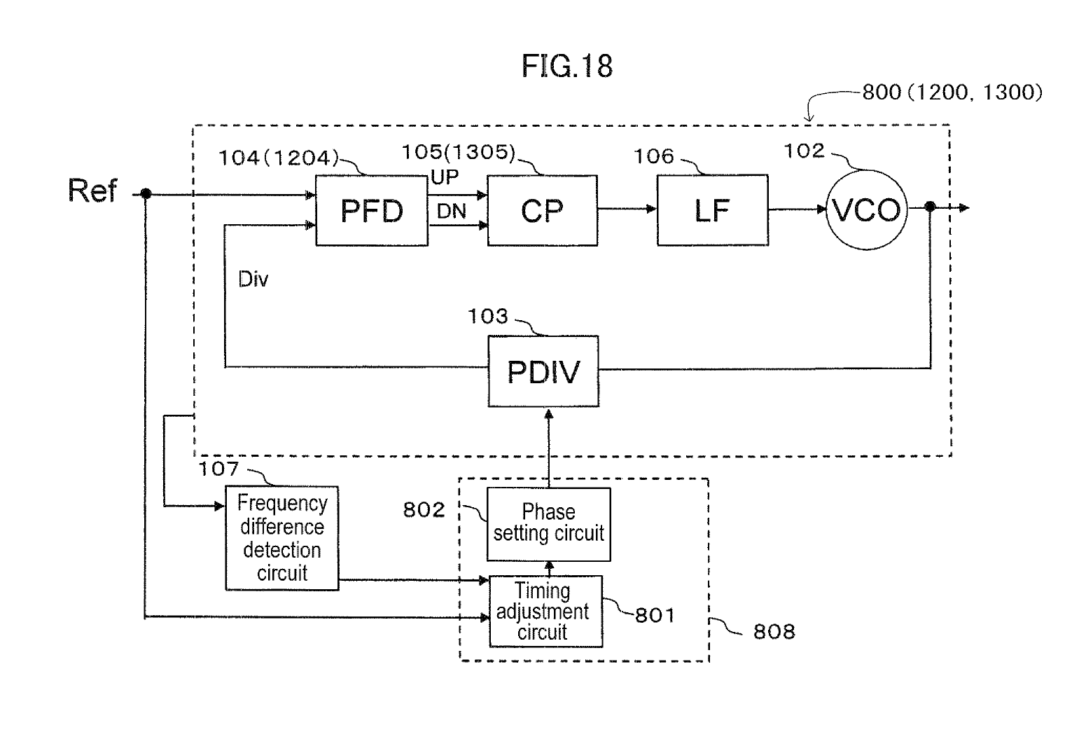

FIG. 18 is a block diagram illustrating a phase-locked loop 800 according to an eighth embodiment of the present invention.

The phase-locked loop 800 according to the eighth embodiment differs in the configuration of the phase adjustment circuit 808 from the phase adjustment circuit 108 of the phase-locked loop 100 of the first embodiment.

A phase adjustment circuit 808 of the present embodiment has a timing adjustment circuit 801 and a phase setting circuit 802.

When receiving as an input the detection circuit, the phase adjustment circuit 808 of this embodiment controls the divider 103 to adjust the phase of the frequency-divided signal to the phase of the reference signal so as to synchronize them, thereby reducing the difference between the phases of the frequency-divided signal and the reference signal.

The timing adjustment circuit 801 inputs thereto the detection signal of the frequency difference detection circuit 107 and the reference signal Ref and outputs a timing signal at the rising edge or failing edge of the reference signal Ref after the input of the detection signal.

When receiving the timing signal, the phase setting circuit 802 sets the value of the counter 103A of the divider 103 to a predetermined value.

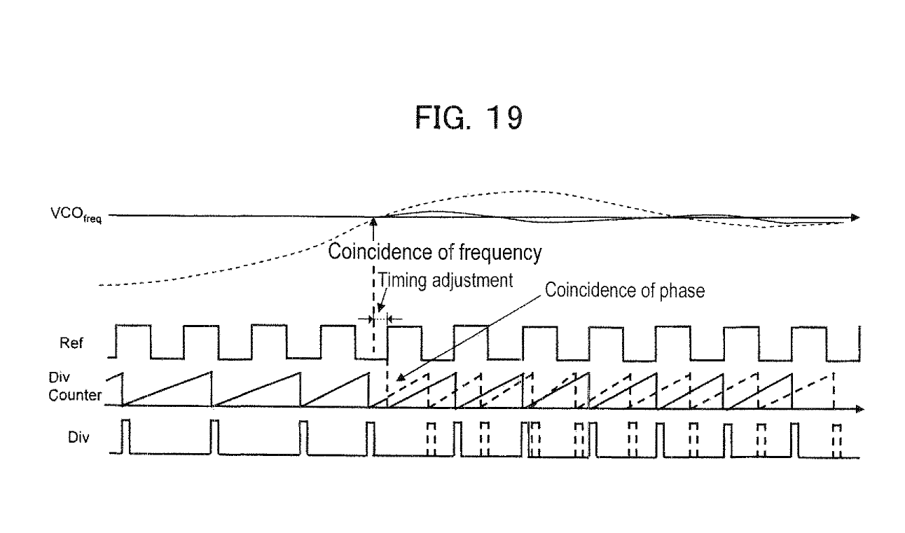

FIG. 19 is a view for explaining operation of the phase-locked loop 800.

Div counter of FIG. 19 represents the value of the counter 103A of the divider 103. When receiving the detection signal from the frequency difference detection circuit 107, the timing adjustment circuit 801 outputs the timing signal at the rising edge of the reference signal Ref. When receiving the timing signal from the timing adjustment circuit 801, the phase setting circuit 802 resets the value of the counter 103A of the divider 103 to zero.

A dotted curve line represents an example of the value of the counter 103A in the case where the value of the counter 103A is not reset. In the case where the value of the counter 103A is reset, the value of the counter 103A changes from the dotted curve line to a solid curve line. The phase setting circuit 802 resets the value of the counter 103A to zero at the rising edge of the reference signal Ref to thereby synchronize the frequencies and phases of the frequency-divided signal and the reference signal.

When the difference detection circuit 202 outputs the detection signal, the phase adjustment circuit 808 synchronizes the phases of the frequency-divided signal and the reference signal to reduce the difference between the phases of the frequency-divided signal and the reference signal.

As described above, according to the phase-locked loop 800 of the present embodiment, the phases are synchronized at the timing at which the frequencies coincide with each other, so that it is possible to reduce frequency overshoot and to shorten the settling time as illustrated in FIG. 19.

### Ninth Embodiment

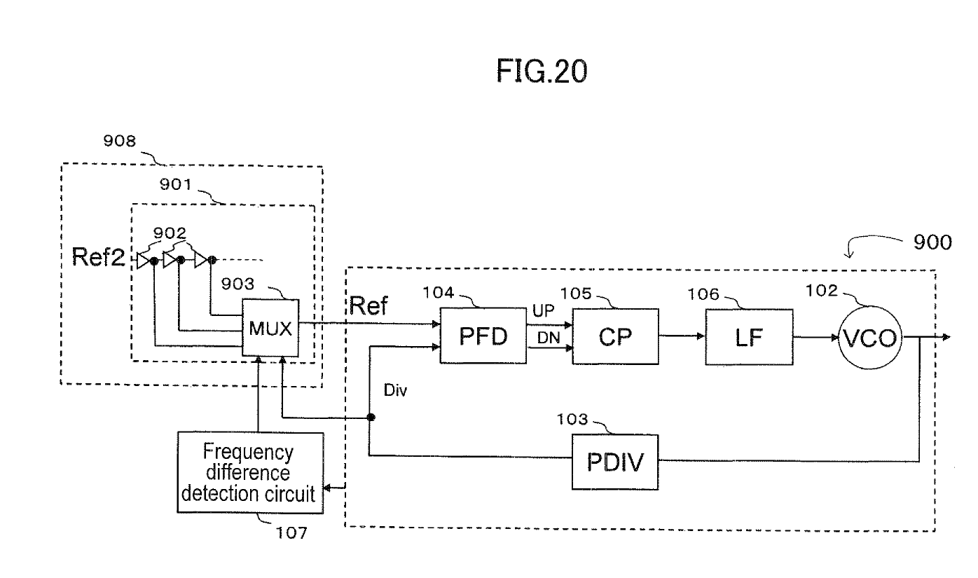

FIG. 20 is a block diagram illustrating a phase-locked loop 900 according to a ninth embodiment of the present invention. In the phase-locked loop 900 according to the ninth embodiment, the configuration of a phase adjustment circuit 908 differs from that of the phase adjustment circuit 108 of the phase-locked loop 100 according to the first embodiment.

The phase adjustment circuit 908 has a delay circuit 901.

The phase adjustment circuit 908 of the present embodiment receives the detection signal and then adjusts the phase of the reference signal to the phase of the frequency-divided signal to thereby synchronize the frequencies and phases of the frequency-divided signal and the reference signal.

Concretely, the delay circuit 901 delays the phase of a reference signal Ref2 by a predetermine delay amount so as to make the phases of the frequency-divided signal and the reference signal Ref coincide with each other. The delay circuit 901 has a plurality of delay stages 902 for delaying the phase of the reference signal Ref2 and a selection circuit 903 for selecting a signal from a plurality of outputs of the delay stages 902. A signal output from the selection circuit 903 is the reference signal Ref. The delay circuit 901 controls the output of which delay stages 903 the selection circuit 903 selects to adjust the delay amount so as to reduce (or eliminate) the difference between the phases of the frequency-divided signal Div and the reference signal Ref.

The selection circuit 903 receives the detection signal from the frequency difference detection circuit 107 and the frequency dividing signal from the divider 103. After receiving the detection signal, the selection circuit 902 selects an output closest in phase to the frequency-divided signal Div from the plurality of outputs of the delay stages 902 at the timing at which the output of the frequency-divided signal Div assumes HT and outputs the selected output as the reference signal Ref. As a result, the frequency-divided signal synchronizes in frequency and phase with the reference signal.

According to the phase-locked loop 900 of the present embodiment, the phases are synchronized at the timing at which the frequencies coincide with each other, so that it is possible to reduce frequency overshoot and to shorten the settling time.

### Tenth Embodiment

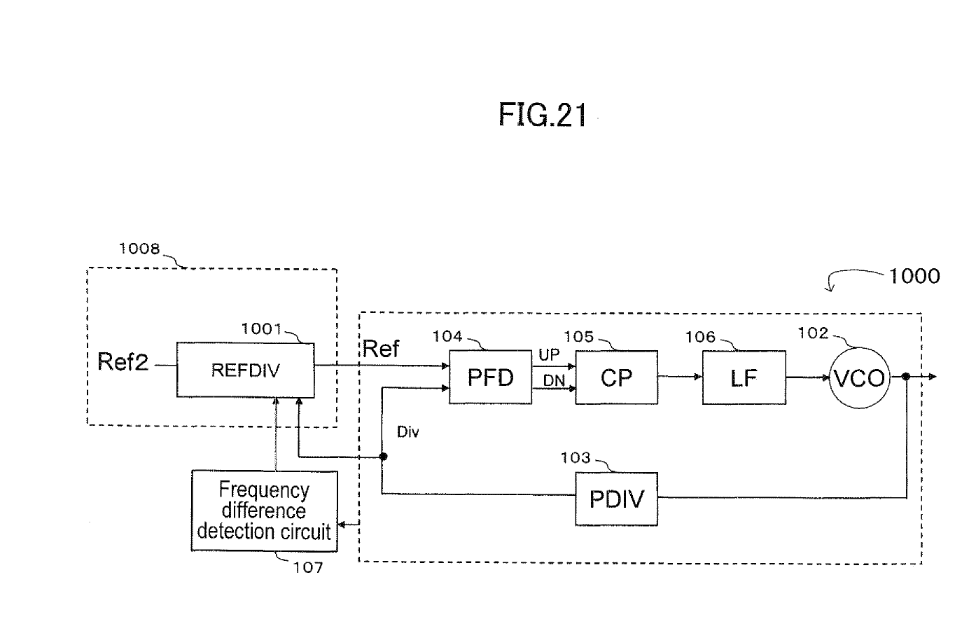

FIG. 21 is a block diagram illustrating a phase-locked loop 1000 according to a tenth embodiment. In the phase-locked loop 1000 according to the tenth embodiment, the configuration of a phase adjustment circuit 1008 differs from that of the phase adjustment circuit 108 of the phase-locked loop 100 according to the first embodiment.

The phase adjustment circuit 1008 has a divider (MUX) 1001.

When receiving the detection signal, the phase adjustment circuit 1008 of the present embodiment combines the phases of the reference signal and the frequency-divided signal so as to synchronize the phases of the reference signal and the frequency-divided signal. The phase adjustment circuit 1008 synchronizes the phases of the frequency-divided signal and the reference signal to reduce the difference between the phases of the frequency-divided signal and the reference signal.

The divider 1001 inputs thereto a reference signal Ref2 having a higher frequency than that the reference signal Ref, divides the reference signal Ref2, and outputs the reference signal Ref1.

When receiving the detection signal from the frequency difference detection circuit 107, a counter (not illustrated) of the divider 1001 is reset at the timing at which the output of the frequency-divided signal Div assumes HI. As a result, the frequency-divided signal synchronizes in frequency and phase with the reference signal.

As a result, the frequency-divided signal synchronizes in frequency and phase with the reference signal.

According to the phase-locked loop of the present embodiment, the phases are synchronized at the timing at which the frequencies coincide with each other, so that it is possible to reduce frequency overshoot and to shorten the settling time.

### Eleventh Embodiment

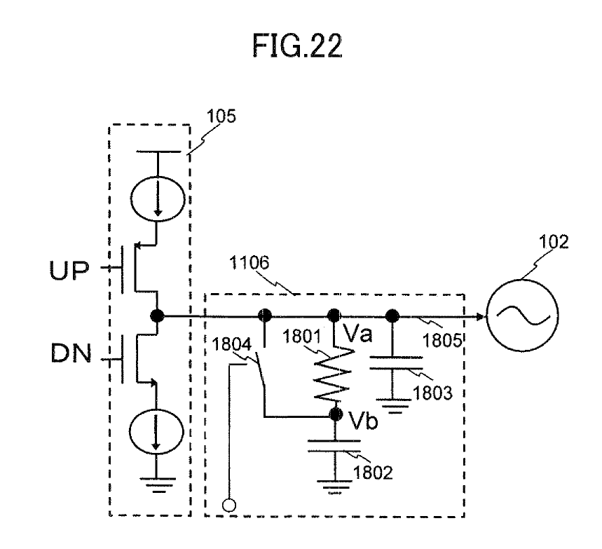

FIG. 22 illustrates a phase-locked loop 1100 according to an eleventh embodiment. The phase-locked loop 1100 has the same configuration as that of the phase-locked loop 100 according to the first embodiment. However, the configuration and function of a loop filter 1106 differ from those of the loop filter 106 of the phase-locked loop 100.

FIG. 22 illustrates the loop filter 1106 of the phase-locked loop 1100 according to the eleventh embodiment.

As illustrated in FIG. 22, the loop filter 1106 has a connection portion 1805, a first capacitor 1803, a resistor 1801, a second capacitor 1802, and a switch 1804. The connection portion 1805 has one end connected to the charge pump 105 and the other end connected to the voltage controlled oscillator 102. The first capacitor 1803 has one end connected to the connection portion 1805 and the other end connected to a first power supply potential (in the present embodiment, ground). The resistor 1801 has one end connected to the connection portion 1805 and the other end connected to the second capacitor 1802. The second capacitor 1802 has one end connected in series to the resistor 1801 and the other end connected to the first power supply potential. The switch 1804 is disposed in parallel to the resistor 1801 and has one end connected to the one end of the second capacitor 1802 and the other end of the switch 1804 is connected to the connection portion 1805. When the switch 1804 is ON, both end is shorted. When the switch 1804 is OFF, both end is opened. The switch 1804 is in an ON state before the frequency difference detection circuit 107 generates the detection signal. After the frequency difference detection circuit 107 generates the detection signal, the switch 1804 is turned OFF.

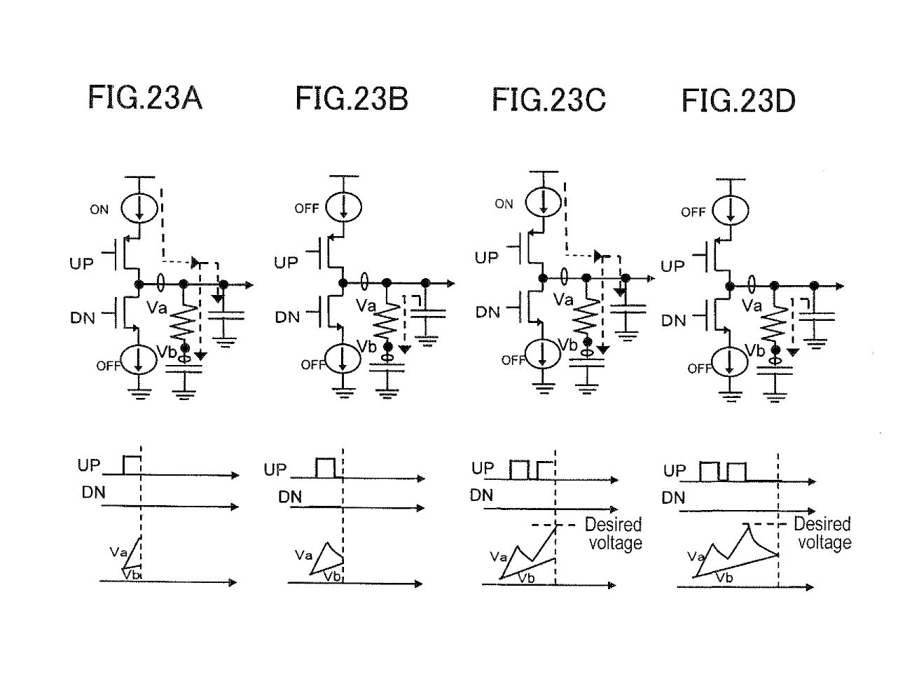

In the loop filter 1106 of FIG. 22, a voltage of the terminal Vb between the resistor 1801 and the second capacitor 1802 changes slower in response than a voltage of the control voltage terminal Va. FIGS. 23A-23D illustrate operation of the loop filter in a typical PLL. As illustrated in FIG. 23A, current is supplied to the loop filter 106 while the phase frequency detector 104 outputs the UP signal. At this time, the voltage of the VP changes slower in response than the voltage of the Va, so that a voltage difference is caused between the Vb and Va. When a voltage difference is caused between the Va and Vb of the loop filter in a state where the frequency difference detection circuit 107 outputs the detection signal and the frequency-divided signal and reference signal synchronize with each other in frequency and phase as illustrated in FIG. 23C, current flows from the first capacitor 1801 to second capacitor 1803 as illustrated in FIG. 23D, with result that the voltage at the Va is brought close to the voltage at the Vb. As a result, the frequency of the voltage controlled oscillator 102 decreases. As described above, the Vb is slower in response than the Va, the voltage of the Va is not stable. It follows that the settling time is increased.

In order to prevent this, in the loop filter 1106 of the present embodiment, the switch 1804 is turned ON until the frequency difference detection circuit 107 outputs the detection signal and is turned OFF when the detection signal is output. While the switch 1804 is in an ON state, the one end of the second capacitor 1802 is connected to the connection portion 1805 through the switch 1804. Therefore, no voltage difference is caused between the Va and Vb, so that the Va and Vb are not changed. As a result, the settling time required for adjusting the frequency and phase of the frequency-divided signal to those of the reference signal can be shortened.

### Twelfth Embodiment

A phase-locked loop 1200 according to a twelfth embodiment will be described. The phase-locked loop 1200 has the same configuration as that of the phase-locked loop 800 according to the eighth embodiment shown in FIG. 18. However, the function of a phase frequency detector 1204 differs from that of the phase frequency detector 104 of the phase-locked loop 800.

The phase frequency detector 1204 according to the present embodiment is configured to stop its operation for a certain time period when the frequency difference detection circuit 107 outputs the detection signal.

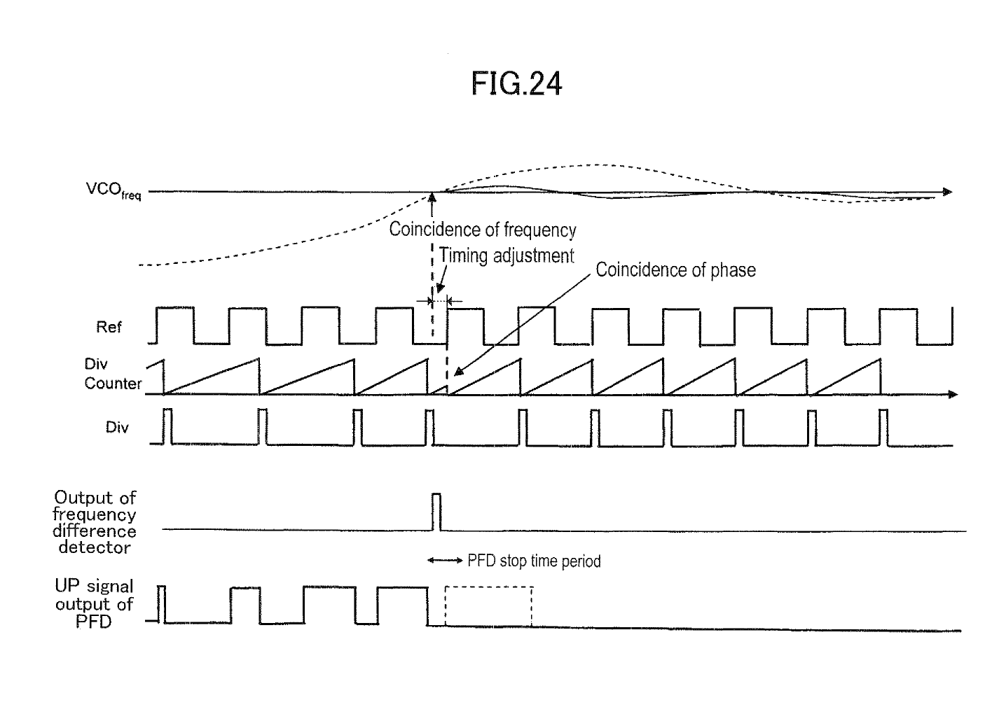

FIG. 24 is a view for explaining operation of the phase-locked loop 1200 according to the present embodiment. As illustrated in FIG. 24, the phase-locked loop 1200 resets the counter of the divider 103 to adjust the phase of the frequency-divided signal to the phase of the reference signal. At this time, the reference signal Ref assumes HI, so that the phase frequency detector outputs the UP signal if the comparator does not have the function of stopping its operation. To prevent this, the phase frequency detector 1204 stops its operation for a certain time period from the time at which the frequency difference detection circuit 107 outputs the detection signal. It is preferable that the phase frequency detector 1204 does not generate the comparison signal at least during the time period from the time when the frequency difference detection circuit 107 generates the detection signal to the time when the phase adjustment circuit 808 synchronizes the phases of the frequency-divided signal and the reference signal. To this end, the phase frequency detector 1204 stops its operation during a certain time period including the time period from the generation of the detection signal by the frequency difference detection circuit 107 to the timing at which the reference signal rises next.

### Thirteenth Embodiment

A phase-locked loop 1300 according to a thirteenth embodiment will be described. The phase-locked loop 1300 has the same configuration as that of the phase-locked loop 800 according to the eighth embodiment illustrated in FIG. 18. However, the function of a charge pump 1305 of the phase-locked loop 1300 differs from that of the charge pump 105 of the phase-locked loop 800. The charge pump 1305 according to the thirteenth embodiment is configured to stop its operation for a certain time period when the frequency difference detection circuit 107 outputs the detection signal.

In the operation of the phase-locked loop 1300, the counter of the divider 103 is reset so as to adjust the phase of the frequency-divided signal to the phase of the reference signal. At this time, the reference signal Ref assumes HI, so that the phase frequency detector 104 outputs the UP signal. To prevent this, a configuration is adopted in which the charge pump 1305 is not activated even if the phase frequency detector 104 outputs the UP signal. It is preferable that the charge pump 1305 does not supply current at least during the time period from the time when the frequency difference detection circuit 107 generates the detection signal to the time when the phase adjustment circuit 108 synchronizes the phases of the frequency-divided signal and the reference signal. To this end, the charge pump 1305 stops its operation during a certain time period including the time period from the generation of the detection signal by the frequency difference detection circuit 107 to the next rising time of the reference signal.

### Fourteenth Embodiment

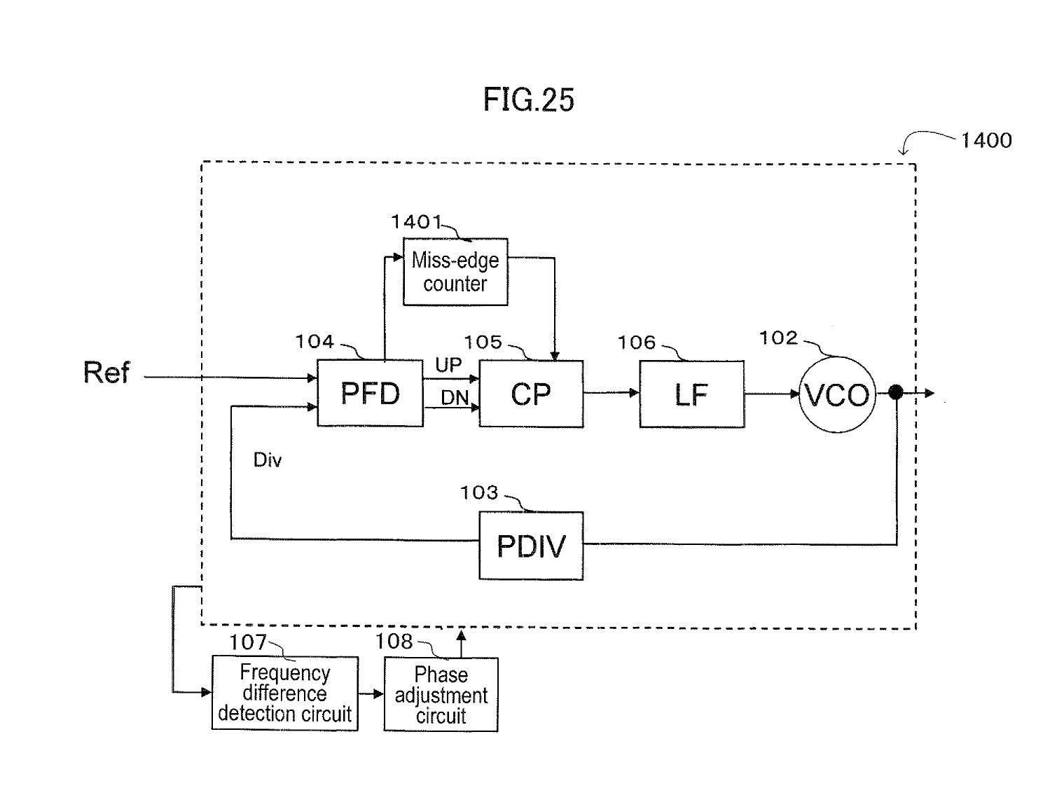

FIG. 25 is a block diagram illustrating a phase-locked loop 1400 according to a fourteenth embodiment.

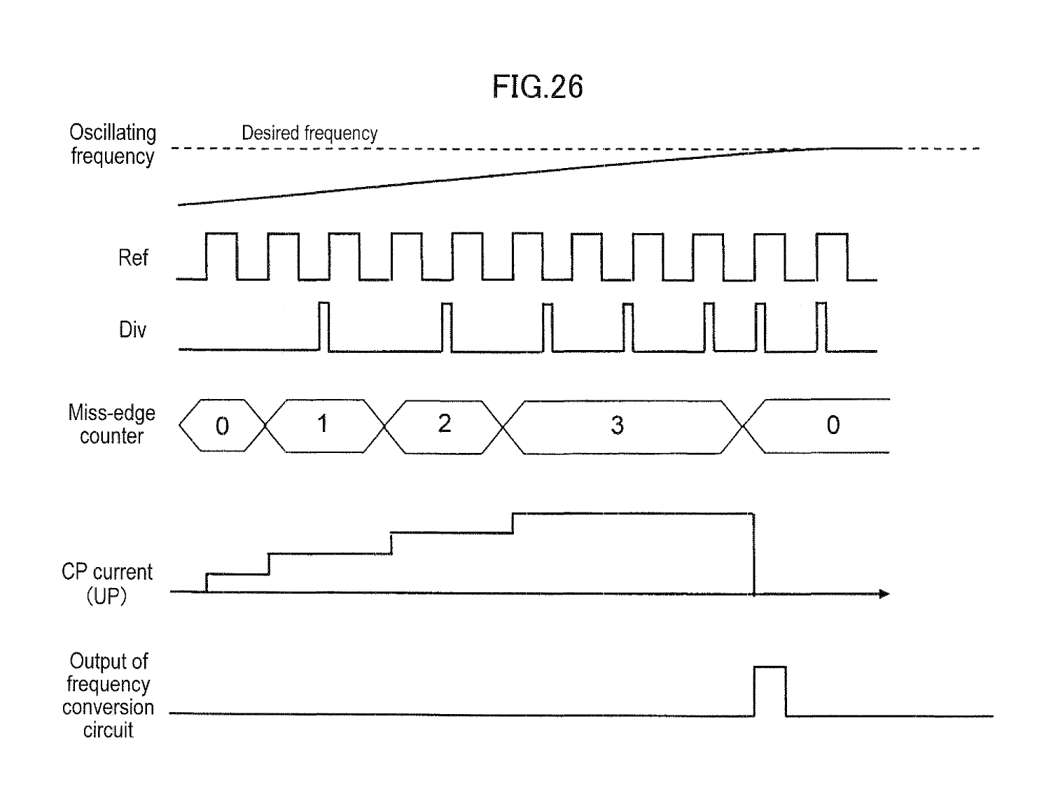

FIG. 26 is a view for explaining operation of the phase-locked loop 1400.

As illustrated in FIG. 25, the phase-locked loop 1400 further includes a miss-edge counter 1401 in addition to the components constituting the phase-locked loop according to the first embodiment.

As illustrated in FIG. 26, the miss-edge counter 1401 counts the number of times that the phase difference between the reference signal and the frequency-divided signal exceeds 2π. The charge pump 105 adjusts the current thereof in accordance with the value of the miss-edge counter 1401.

When the detection signal is output from the frequency difference detection circuit 107, the counter of the miss-edge counter 1401 is reset to zero. As a result, the current of the charge pump is returned to a normal value.

### Fifteenth Embodiment

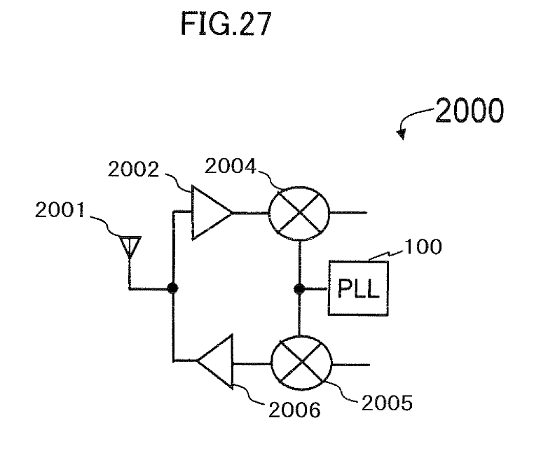

FIG. 27 is a radio communication device 2000 according to a fifteenth embodiment.

The radio communication device 2000 has an antenna 2001 for transmitting/receiving a radio signal, a first amplifier 2002 that amplifies the radio signal received by the antenna 2001 to generate an amplified signal, a phase-locked loop 100 that generates an oscillation signal, a first mixer circuit 2004 that down-converts the amplified signal by the oscillation signal to generate a reception baseband signal, a second mixer circuit 2005 that up-converts a transmission baseband signal by an oscillation signal to generate a transmission signal, and a second amplifier 2006 that amplifies the transmission signal to output a radio signal.

In the radio communication device 2000 according to the present embodiment, the phase-locked loop 100 can shorten the settling time at the switching time of the frequency of the oscillation signal.

While certain embodiments have been described, these embodiments have been presented by way of example only, and are not intended to limit the scope of the inventions. Indeed, the novel methods and systems described herein may be embodied in a variety of other forms; furthermore, various omissions, substitutions and changes in the form of the methods and systems described herein may be made without departing from the spirit of the inventions. The accompanying claims and their equivalents are intended to cover such forms or modifications as would fall within the scope and spirit of the inventions.

What is claimed is:

1. A phase-locked loop comprising:
a voltage controlled oscillator that generates an oscillation signal including an oscillation frequency corresponding to a control signal;
a divider that divides the oscillation signal to generate a frequency-divided signal;
a phase frequency detector that compares the phases of the frequency-divided signal and a reference signal to generate a comparison signal;
a charge pump that generates current corresponding to the comparison signal;
a filter that filters the current to generate the control signal;
a detection circuit that generates a detection signal when the difference between a value of a constant multiple of the frequency of the frequency-divided signal and a value of a constant multiple of the frequency of the reference signal becomes local minimum; and
a phase adjustment circuit that synchronizes the phases of the frequency-divided signal and the reference signal when the detection signal is generated.

2. The phase-locked loop according to claim 1, wherein
the detection circuit comprises a calculation section that calculates the difference between a value of a constant multiple of the frequency of the frequency-divided signal and a value of a constant multiple of the frequency of the reference signal and a retaining section that retains the difference between a value of a constant multiple of the frequency of the frequency-divided signal and a value of a constant multiple of the frequency of the reference signal, and
in the case where the sign of the difference between a value of a constant multiple of the frequency of the frequency-divided signal and value of a constant multiple of the frequency of the reference signal which is retained by the retaining section is plus and where the difference between a value of a constant multiple of the frequency of the frequency-divided signal and a value of a constant multiple of the frequency of the reference signal which is calculated by the calculated section is minus, the detection circuit generates the detection signal.

3. The phase-locked loop according to claim 1, wherein
the detection circuit comprises a calculation section that calculates the difference between a value of a constant multiple of the frequency of the frequency-divided signal and a value of a constant multiple of the frequency of the reference signal and a retaining section that retains the difference between a value of a constant multiple of the frequency of the frequency-divided signal and a value of a constant multiple of the frequency of the reference signal, and
in the case where the sign of the difference between a value of a constant multiple of the frequency of the frequency-divided signal and a value of a constant multiple of the frequency of the reference signal which is retained by the retaining section is minus and where the difference between a value of a constant multiple of the frequency of the frequency-divided signal and a value of a constant multiple of the frequency of the reference signal which is calculated by the calculated section is plus, the detection circuit generates the detection signal.

4. The phase-locked loop according to claim 1, wherein
the detection circuit comprises a calculation section that calculates the difference between a value of a constant multiple of the frequency of the frequency-divided signal and a value of a constant multiple of the frequency of the reference signal, and
in the case where the difference between a value of a constant multiple of the frequency of the frequency-divided signal and a value of a constant multiple of the frequency of the reference signal which is calculated by the calculation section is zero, the detection circuit generates the detection signal.

5. The phase-locked loop according to claim 1, wherein,
when the detection signal is generated, the phase adjustment circuit synchronizes the phase of the frequency-divided signal with the phase of the reference signal.

6. The phase-locked loop according to claim 1, wherein,
when the detection signal is generated, the phase adjustment circuit synchronizes the phase of the reference signal with the phase of the frequency-divided signal.

7. The phase-locked loop according to claim 2, wherein
the calculation section calculates the difference between a value of a constant multiple of the frequency of the frequency-divided signal and a value of a constant multiple of the frequency of the reference signal from the difference between the frequency dividing number of the divider and the number of cycles of the oscillation signal included in one period of the reference signal.

8. The phase-locked loop according to claim 2, wherein
the divider has a counter for counting the number of cycles of the oscillation signal, and
the calculation section calculates the difference between a value of a constant multiple of the frequency of the frequency-divided signal and a value of a constant multiple of the frequency of the reference signal from the difference between the counter value and counter value measured one period before the reference signal.

9. The phase-locked loop according to claim 2, wherein
the calculation section comprises a phase difference detector for detecting the phase difference between the reference signal and the frequency-divided signal and calculates the difference between a value of a constant multiple of the frequency of the frequency-divided signal and a value of a constant multiple of the frequency of the reference signal from the phase difference detected by the phase difference detector and phase difference one period before the detection.

10. The phase-locked loop according to claim 2, wherein,
in the case where the phase of the reference signal advances with respect to the phase of the frequency-divided signal, the phase frequency detector generates a first comparison signal having a first pulse width ranging from the rising edge of the reference signal to the rising edge of the frequency-divided signal; while in the case where the phase of the reference signal delays with respect to the phase of the frequency-divided signal, the phase frequency detector generates a second comparison signal having a second pulse width ranging from the rising edge of the frequency-divided signal to the rising edge of the reference signal, and
the calculation section of the detection section calculates the difference between a value of a constant multiple of the frequency of the frequency-divided signal and a value of a constant multiple of the frequency of the reference signal from the difference between the first or second pulse width and the previous first or second pulse width of the comparison signal.

11. The phase-locked loop according to claim 5, wherein
the divider comprises a counter for counting the number of cycles, and
the phase adjustment circuit controls the counter such that the counter value is reset when the detection signal is generated.

12. The phase-locked loop according to claim 6, wherein
the phase adjustment circuit comprises a delay circuit for delaying the phase of the reference signal by a predetermined delay amount, and
when the detection signal is generated, the delay circuit adjusts the predetermined delay amount so as to reduce the difference between the phases of the frequency-divided signal and the reference signal.

13. The phase-locked loop according to claim 6, wherein
the phase adjustment circuit comprises a second divider that frequency-divides a first reference signal to generate the reference signal,
the second divider comprises a counter for counting the number of cycles of the first reference signal, and
when the detection signal is generated, the second divider resets the counter value.

14. The phase-locked loop according to claim 2, wherein
the detection circuit predicts the difference between a value of a constant multiple of the frequency of the frequency-divided signal and a value of a constant multiple of the frequency of the reference signal to be detected one period later from a first difference and a second difference, the first difference being the difference between a value of a constant multiple of the frequency of the frequency-divided signal and a value of a constant multiple of the frequency of the reference signal and difference between a value of a constant multiple of the frequency of the frequency-divided signal and a value of a constant multiple of the frequency of the reference signal which is retained by the retaining section and the second difference being the difference between a value of a constant multiple of the frequency of the frequency-divided signal and a value of a constant multiple of the frequency of the reference signal, and
when the predicted difference between a value of a constant multiple of the frequency of the frequency-divided signal and a value of a constant multiple of the frequency of the reference signal becomes local minimum, the detection circuit generates the detection signal.

15. The phase-locked loop according to claim 1, wherein
the filter comprises:
a connection portion having one end connected to the charge pump and the other end connected to the voltage controlled oscillator;
a resistor having one end connected to the connection portion;
a capacitor having one end connected in series to the resistor and the other end connected to a first power supply potential;
a switch disposed in parallel to the resistor, having one end connected to the one end of the capacitor, and having the other end connected to the connection portion when being ON while disconnected from the connection portion when being OFF, the switch being in an ON state before the detection circuit generates the detection signal and being turned OFF after the detection circuit generates the detection signal.

16. The phase-locked loop according to claim 1, wherein
the phase frequency detector does not generate the comparison signal for a certain time period from the time when the detection circuit generates the detection signal.

17. The phase-locked loop according to claim 1, wherein
the charge pump does not output the current for a certain time period from the time when the detection circuit generates the detection signal.

18. The phase-locked loop according to claim 1, comprising:
a counter that counts the number of times that the phase difference between the reference signal and the frequency-divided signal exceeds 2π and outputs a signal having a level corresponding to the number of counts, wherein
the charge pump outputs current corresponding to the signal, and
when the detection circuit generates the detection signal, the value of the counter is reset.

19. A radio communication device comprising:
an antenna for transmitting/receiving a radio signal;
a first amplifier that amplifies the radio signal received by the antenna to generate an amplified signal;
a second amplifier that amplifies a transmission signal to generate a radio signal;
a phase-locked loop as claimed in claim 1 that generates an oscillating signal;
a first mixer circuit that down-converts the amplified signal by the oscillating signal to generate a reception baseband signal; and
a second mixer circuit that up-converts a transmission baseband signal and an oscillating signal to generate the transmission signal.
